(19) United States
(12) Patent Application Publication
(10) Pub. No.: US 2026/0366131 A1
(43) Pub. Date: Nov. 19, 2026

(54) DEPOSITION MASK, METHOD FOR MANUFACTURING THE DEPOSITION MASK, AND ELECTRONIC DEVICE

(71) Applicant: SAMSUNG DISPLAY CO., LTD., YONGIN-SI (KR)

(72) Inventors: Ji Hye HAN, Yongin-si (KR); Chul Min BAE, Yongin-si (KR)

(21) Appl. No.: 19/419,359

(22) Filed: Dec. 15, 2025

(30) Foreign Application Priority Data
May 15, 2025 (KR) 10-2025-0063408

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes a first inorganic layer including a first region on a first surface of a base substrate, a second region on a second surface of the base substrate, and a third region on a side surface of the base substrate; cell openings penetrating the first region of the first inorganic layer; and opening patterns penetrating the second region of the first inorganic layer and the base substrate.

### CROSS-REFERENCE TO RELATED APPLICATION

This U.S. non-provisional patent application claims priority under 35 U.S.C. §119 to Korean Patent Application No. 10-2025-0063408 filed on May 15, 2025, in the Korean Intellectual Property Office, the entire contents of which are incorporated herein by reference.

### TECHINICAL FIELD

The present disclosure relates to a deposition mask, a method for manufacturing the deposition mask, and an electronic device.

### DISCUSSION OF THE RELATED ART

In recent years, due to the increasing demand in high-resolution information display devices, research and development have been continuously conducted on display devices. These display devices may include organic light-emitting diode (OLED) displays, micro-OLED displays, flat-panel displays, or foldable panel displays. However, during the manufacturing of deposition masks used in these devices, edge breakage of the base substrate, such as chipping defects caused by etching solution infiltration, has emerged as a persistent problem. Accordingly, there is a demand for deposition mask structures and manufacturing methods capable of improving substrate edge integrity.

### SUMMARY

Embodiments of the present inventive concept provide a deposition mask including a first inorganic layer including a first region disposed on a first surface of a base substrate, a second region disposed on a second surface of the base substrate, and a third region disposed on a third surface of the base substrate. The first surface and the second surface are major surfaces of the base substrate and the third surface is a minor surface of the base substrate. The deposition mask further includes cell openings penetrating the first region of the first inorganic layer and opening patterns penetrating the second region of the first inorganic layer and the base substrate. The opening patterns overlap the cell openings.

The deposition mask may further include a second inorganic layer including a first region disposed between the first surface of the base substrate and the first region of the first inorganic layer, a second region disposed between the second surface of the base substrate and the second region of the first inorganic layer, and a third region disposed between the third surface of the base substrate and the third region of the first inorganic layer.

The deposition mask may further include an amorphous carbon layer disposed between the first surface of the base substrate and the first region of the first inorganic layer.

The second region of the second inorganic layer may be disposed directly on the second region of the first inorganic layer.

The first inorganic layer may include a silicon nitride and the second inorganic layer may include a silicon oxide.

Embodiments of the present inventive concept provide a method for manufacturing a deposition mask, the method includes forming a first inorganic layer on a base substrate, where the first inorganic layer includes a first region, a second region, and a third region disposed on a first surface, a second surface, and a third surface of the base substrate, respectively, forming a first hard mask layer on the first surface of the base substrate, and forming cell openings in the first hard mask layer by etching the first hard mask layer and the first region of the first inorganic layer.

The method for manufacturing a deposition mask may further include forming a second inorganic layer on the first hard mask layer and the first inorganic layer, where the second inorganic layer includes a first region, a second region, and a third region disposed on the first hard mask layer, the second region of the first inorganic layer, and the third region of the first inorganic layer, respectively. The method may further include forming a second hard mask layer on the first region of the second inorganic layer, forming a third inorganic layer on the second hard mask layer, forming a photoresist pattern on the third inorganic layer, forming cell openings in the third inorganic layer by patterning the photoresist pattern, forming cell openings in the second hard mask layer, and forming cell openings in the first region of the second inorganic layer.

The photoresist pattern may partially expose an edge of the third inorganic layer.

An edge of the third inorganic layer may be etched in the forming cell openings in the third inorganic layer.

An edge of the second hard mask layer may be etched in the forming cell openings in the second hard mask layer.

An edge of the second inorganic layer may be partially etched in the forming cell openings in the first region of the second inorganic layer.

The second hard mask layer may be removed in the forming cell openings in the first hard mask layer.

The first region of the second inorganic layer may be removed in the forming cell openings in the first region of the first inorganic layer.

The method for manufacturing a deposition mask may further include ashing the first hard mask layer.

The method for manufacturing a deposition mask may further include forming opening patterns by etching the second region of the second inorganic layer, the second region of the first inorganic layer, and the base substrate.

In the forming opening patterns, the side surface of the base substrate may be protected by the first inorganic layer and the second inorganic layer.

The method for manufacturing a deposition mask may further include forming opening patterns by etching the second region of the second inorganic layer, the second region of the first inorganic layer, the base substrate, and the first region of the first inorganic layer.

In the forming opening patterns, the side surface of the base substrate may be protected by the first inorganic layer and the second inorganic layer.

The first hard mask layer and the second hard mask layer may be amorphous carbon layers.

Embodiments of the present inventive concept provide an electronic device including a display device including a display panel formed using a deposition mask, a memory having a stored application for operating the electronic device including the display device, and a processor configured to execute the application stored in the memory. The deposition mask includes a first inorganic layer including a first region disposed on a first surface of a base substrate, a second region disposed on a second surface of the base substrate, and a third region disposed on a third surface of the base substrate, where the first surface is opposite and parallel to the second surface, and wherein the third surface crosses the first surface and the second surface, cell openings penetrating the first region of the first inorganic layer, and opening patterns penetrating the second region of the first inorganic layer and the base substrate.

The deposition mask may further include a second inorganic layer including a first region disposed between the first surface of the base substrate and the first region of the first inorganic layer, a second region disposed between the second surface of the base substrate and the second region of the first inorganic layer, and a third region disposed between the third surface of the base substrate and the third region of the first inorganic layer.

The deposition mask may further include an amorphous carbon layer disposed between the first surface of the base substrate and the first region of the first inorganic layer.

According to the above-described embodiments, by covering and protecting the edges of the base substrate with an inorganic layer, a phenomenon in which an etching solution infiltrates during the manufacturing process of the deposition mask and causes edge breakage of the base substrate can be minimized.

### BRIEF DESCRIPTION OF THE DRAWINGS

FIG. 1 is a side view illustrating an embodiment of a deposition apparatus.

FIGS. 2, 3, 4, and 5 are side views illustrating embodiments of a deposition mask.

FIG. 6 is a block diagram illustrating a display device according to an embodiment of the present disclosure.

FIG. 7 is a block diagram illustrating a sub-pixel of the display device according to an embodiment of the present disclosure.

FIG. 8 is a plan view illustrating the display panel according to an embodiment of the present disclosure.

FIG. 9 is an exploded perspective view showing a portion of the display panel of FIG. 8.

FIG. 10 is a block diagram of an electronic device according to an embodiment of the present disclosure.

FIG. 11 is a schematic diagram of an electronic device according to various embodiments of the present disclosure.

FIGS. 12, 13, 14, 15, 16, 17, 18, 19, and 20 are cross-sectional views of process steps of a method for manufacturing a deposition mask according to an embodiment of the present disclosure.

FIGS. 21, 22, 23, 24, 25, 26, and 27 are cross-sectional views of process steps of a method for manufacturing a deposition mask according to an embodiment of the present disclosure.

FIGS. 28, 29, 30, 31, and 32 are cross-sectional views of process steps of a method for manufacturing a deposition mask according to an embodiment of the present disclosure.

FIGS. 33, 34, 35, and 36 are cross-sectional views of process steps of a method for manufacturing a deposition mask according to an embodiment of the present disclosure.

### DETAILED DESCRIPTION OF THE EMBODIMENTS

Hereinafter, embodiments of the present disclosure are described in detail with reference to the accompanying drawings. The present disclosure is not necessarily limited to the embodiments described herein, and may be embodied in other forms. However, the embodiments described herein are provided to explain the technical idea of the present disclosure in detail to a person skilled in the art to which the present disclosure pertains.

Throughout the specification, when a part is “connected” to another part, this may include a case where the part is “directly connected” to the other part. Additionally, this may include a case where the part is “indirectly connected” to the other part with another element interposed therebetween. The terminology used herein is for the purpose of describing particular embodiments and is not necessarily intended to limit the invention. Throughout the specification, when it is described that a part may “include” a component, this may represent that other components may be further included, rather than excluding other components, unless otherwise specified. “At least one of X, Y, or Z”, and “at least one selected from the group consisting of X, Y, or Z”, can be interpreted as one X, one Y, one Z, or any combination of two or more of X, Y, or Z (e.g., XYZ, XY, YZ, ZX). Here, “and/or” may include all combinations of one or more of the corresponding configurations.

Here, terms such as first, second, and the like may be used to describe various components, but these components are not necessarily limited thereto. These terms may be used to distinguish one component from another. Accordingly, a first component may refer to a second component without departing from the teachings of the present invention. Similarly, the second element could also be termed the first element.

Spatially relative terms such as “below”, “above”, and the like may be used for purposes of description, thereby describing a relationship of one element or feature to another element(s) or feature(s), as shown in the figures. Spatially relative terms are intended to include different directions in use, operation, and/or manufacture, in addition to the directions depicted in the figures. For example, if the device shown in the figure is flipped over, elements depicted as being “below” other elements or features may be positioned in a direction “above” the other elements or features. Thus, in an embodiment, the term “below” may include both directions above and below. In addition, the device may be directed in another direction (e.g., rotated 90 degrees or in another direction), and thus, the spatially relative terms used herein may be interpreted accordingly.

Various embodiments may be described with reference to the figures schematizing ideal embodiments. Accordingly, it will be appreciated that the shapes may vary based on, for example, tolerances and/or manufacturing techniques. Additionally, same reference numerals may be used to indicate the same elements disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Embodiments of the present disclosure provide a deposition mask including a base substrate and a plurality of inorganic layers disposed on a first, a second, and a side surfaces of the base substrate. The inorganic layers include a first inorganic layer and a second inorganic layer, and may further include a hard mask layer formed of amorphous carbon. Cell openings are formed through the inorganic layers on the first surface of the base substrate, and opening patterns are formed through the inorganic layers and the base substrate. By covering the side surfaces of the base substrate with the inorganic layers during formation of the cell openings and opening patterns, embodiments of the present disclosure minimize infiltration of etching solution into the substrate and thereby reduce chipping or breakage at the substrate edges, thus improving durability and reliability of the deposition mask for high-resolution display manufacturing.

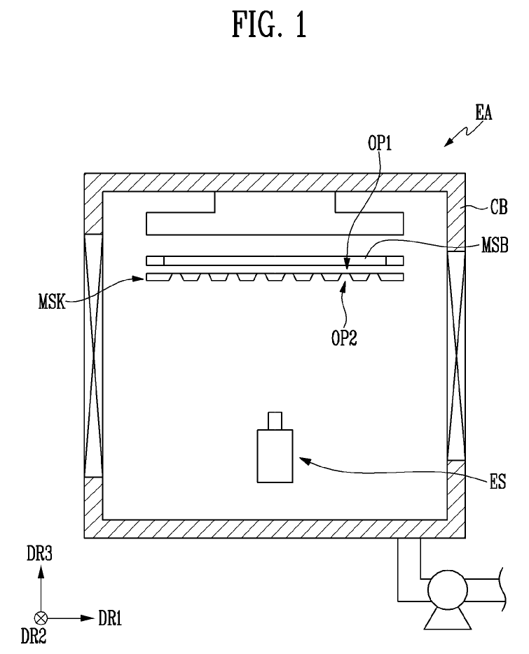

FIG. 1 is a side view illustrating an embodiment of a deposition apparatus.

Referring to FIG. 1, the deposition apparatus EA according to an embodiment may include a chamber CB, a deposition source ES, and a deposition mask MSK.

The chamber CB may have an interior space. The interior space of the chamber CB may be a workspace prepared for a deposition process. An object serving as a deposition target may be disposed (or placed) inside the chamber CB. For example, a main substrate MSB may be disposed inside the chamber CB. In some embodiments, the chamber CB may further include a temperature control unit, a gas inlet port, or a vacuum pump connection configured to maintain a controlled pressure and atmosphere during deposition.

The deposition source ES may be disposed inside the chamber CB. The deposition source ES may store a deposition material and supply the deposition material to the interior space of the chamber CB. The deposition material may include a material that forms a specific pattern (e.g., a light emitting layer) on the main substrate MSB. The deposition source ES may apply energy (e.g., thermal energy, light energy, or vibrational energy) to the deposition material to vaporize or sublimate the deposition material. For example, the deposition source ES may include a heater, and may heat the deposition material inside the deposition source ES using the heater, thereby melting or sublimating the deposition material. The deposition source ES may be replaceable. The deposition source ES may be replaced with a new deposition source when the deposition material is exhausted. In an embodiment, the deposition source ES may include multiple source units configured to supply different deposition materials sequentially or simultaneously to form multilayer structures such as stacked emission layers or barrier layers on the main substrate MSB. In an embodiment, the deposition source ES may be disposed outside the chamber CB and connected to the chamber CB via a nozzle or conduit configured to introduce the vaporized deposition material into the chamber CB

A deposition mask MSK may be placed between the main substrate MSB and the deposition source ES. The deposition mask MSK may be aligned to face the deposition target. A deposition mask MSK may block the deposition material in some areas, and might not block the deposition material in other some areas. For example, the deposition mask MSK may be configured to selectively block the deposition material in predetermined areas while permitting passage of the deposition material through other areas. Accordingly, the deposition material may be selectively deposited on specific areas of the deposition target. Cell openings OP1 may be defined as through-holes or apertures formed in the deposition mask MSK that permit the deposition material to pass therethrough. The deposition mask MSK may include opening patterns OP2 that overlap the cell openings OP1. The cell opening OP1 and the opening pattern OP2 may overlap in a third direction DR3. The deposition material may be provided to the deposition target (or the main substrate MSB) through the cell opening OP1 and the opening pattern OP2.

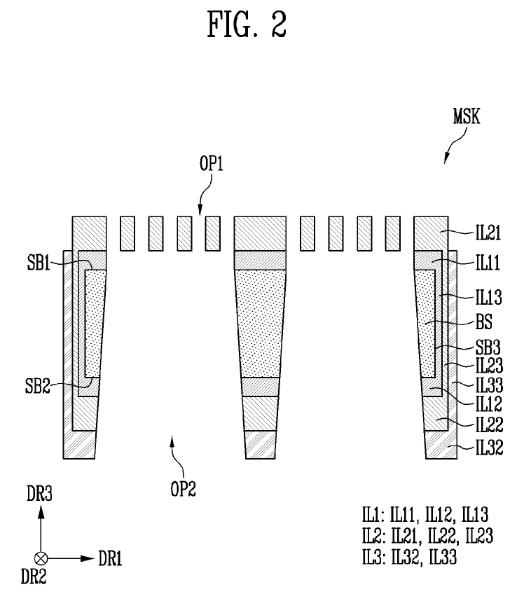

FIGS. 2-5 are side views illustrating a deposition mask according to an embodiment of the present disclosure.

Referring to FIG. 2, the deposition mask MSK may include a base substrate BS and inorganic layers including first inorganic layer IL1, second inorganic layer IL2, and third inorganic layer IL3.

The base substrate BS may include silicon, but is not necessarily limited thereto. A first inorganic layer IL1 may be disposed on the base substrate BS. In some cases, the base substrate BS may include at least one of glass, quartz, sapphire, or a ceramic substrate. The base substrate BS may further include a composite multilayer structure.

The first inorganic layer IL1 may be disposed on a first surface (or front surface) SB1, a second surface (or back surface) SB2, and a third surface (or side surface) SB3 of the base substrate BS. For example, the first inorganic layer IL1 may include a first region IL11 disposed on the first surface (or front surface) SB1 of the base substrate BS, a second region IL12 disposed on the second surface (or back surface) SB2 of the base substrate BS, and a third region IL13 disposed on the third surface (or side surface) SB3 of the base substrate BS. In some cases, for example, the first inorganic layer IL1 may partially surround the base substrate BS. In an embodiment, the first inorganic layer IL1 may include silicon oxide (SiOx), but is not necessarily limited thereto.

A second inorganic layer IL2 may be disposed on the first inorganic layer IL1. The second inorganic layer IL2 may be disposed on the first surface SB1, the second surface SB2, and the third surface SB3 of the base substrate BS. For example, the second inorganic layer IL2 may include a first region IL21 disposed on the first region IL11 of the first inorganic layer IL1, a second region IL22 disposed on the second region IL12 of the first inorganic layer IL1, and a third region IL23 disposed on the third region IL13 of the first inorganic layer IL1. In some cases, for example, the second inorganic layer IL2 may partially surround the first inorganic layer IL1. In an embodiment, the second inorganic layer IL2 may include silicon nitride (SiNx), but is not necessarily limited thereto. In some cases, for example, the second inorganic layer IL2 and the first inorganic layer IL1 may have the same or different materials.

A third inorganic layer IL3 may be disposed on the second inorganic layer IL2. The third inorganic layer IL3 may be disposed on the second surface SB2 and the third surface SB3 of the base substrate BS. In some cases, the third inorganic layer IL3 may partially surround the second inorganic layer IL2. For example, the third inorganic layer IL3 may surround two sides of the second inorganic layer IL2

The third inorganic layer IL3 may include a second region IL32 disposed on the second region IL22 of the second inorganic layer IL2, and a third region IL33 disposed on the third region IL23 of the second inorganic layer IL2. In an embodiment, the third inorganic layer IL3 may include silicon nitride (SiNx), but is not necessarily limited thereto. In some cases, for example, the third inorganic layer IL3 and the second inorganic layer IL2 may have the same or different materials.

In an embodiment, the third inorganic layer IL3 may have a shape with partially etched edges. For example, the third inorganic layer IL3 may expose the first region IL21 of the second inorganic layer IL2. In an embodiment, even though the third inorganic layer IL3 is partially etched to expose the first region IL21 of the second inorganic layer IL2, the third region IL23 of the second inorganic layer IL2 may be covered by the third inorganic layer IL3. Thus, the third surface SB3 (or edge) of the base substrate BS may remain protected during the process of manufacturing the deposition mask MSK. In some embodiments, the third inorganic layer IL3 may be selectively etched to form a tapered profile along the side regions of the third inorganic layer IL3. In some embodiments, the thickness of the third region IL33 may be greater than the thickness of the second region IL32.

The deposition mask MSK may include cell openings OP1 and opening patterns OP2. The cell openings OP1 may penetrate the first region IL21 of the second inorganic layer IL2 in the third direction DR3. Accordingly, deposition material may be provided to a main substrate MSB through the cell openings OP1. In some embodiments, the cell openings OP1 may have a tapered or curved sidewall profile. In other embodiments, the cell openings OP1 may be arranged in a matrix or staggered layout to optimize uniformity of deposition across the main substrate MSB.

The opening patterns OP2 may overlap the cell openings OP1 in the third direction DR3. The opening patterns OP2 may penetrate the second region IL32 of the third inorganic layer IL3, the second region IL22 of the second inorganic layer IL2, the second region IL12 of the first inorganic layer IL1, the base substrate BS, and the first region IL11 of the first inorganic layer IL1 measured in the third direction DR3. Accordingly, deposition material may be provided to the main substrate MSB through the opening patterns OP2. In an embodiment, the opening patterns OP2 may be configured with varying widths in the first direction DR1 or second direction DR2. For example, the width of the opening patterns OP2 adjacent to the second region IL32 of the third inorganic layer IL3 is greater than the width of the opening patterns OP2 adjacent to the first region IL11 of the first inorganic layer IL1.

According to the embodiments described above, the third surface SB3 (or edge) of the base substrate BS may be sequentially covered by the first inorganic layer IL1, the second inorganic layer IL2, and the third inorganic layer IL3. Accordingly, a phenomenon in which an etching solution infiltrates during the manufacturing process of the deposition mask MSK and causes edge breakage of the base substrate BS, such as chipping defects, can be minimized.

In an embodiment, the deposition mask includes a base substrate having a first surface, a second surface opposite to the first surface, and a third surface forming a side surface that extends between the first and second surfaces. For example, the first surface and the second surface are major surfaces of the base substrate and the third surface is a minor surface of the base substrate. For example, the major surfaces are the top and bottom surfaces and the minor surface is a side surface. A first inorganic layer is disposed to continuously cover the first, second, and third surfaces of the base substrate, such that a first region of the inorganic layer lies on the first surface, a second region lies on the second surface, and a third region lies on the third surface. By extending the inorganic layer to all three surfaces, the side edge of the base substrate is reliably protected during subsequent processing. A plurality of cell openings is formed to penetrate the first region of the inorganic layer so that deposition material can selectively pass through to a target substrate. In addition, a plurality of opening patterns is formed to penetrate the second region of the inorganic layer and extend through the base substrate, thereby enabling alignment and stable passage of deposition material. This configuration ensures that the inorganic layer not only defines precise deposition regions but also acts as a protective barrier against infiltration of etchants along the exposed edges of the base substrate. In some embodiments, the cell openings and the opening patterns may be formed to overlap or connect in a vertical direction, thereby establishing a continuous passage through the deposition mask for the controlled transfer of deposition material.

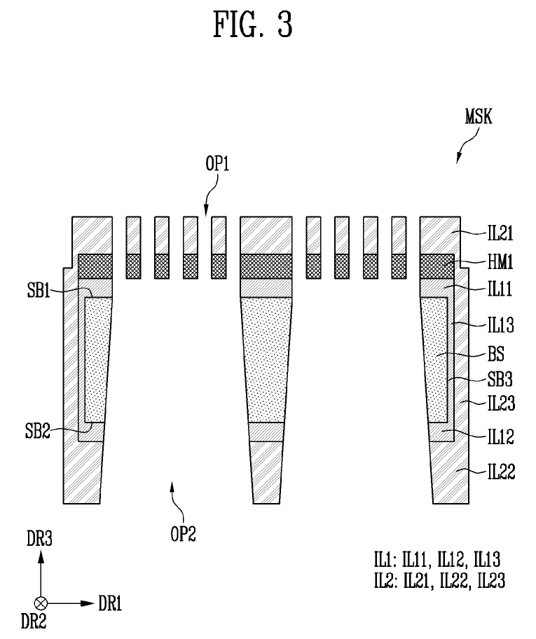

Referring to FIG. 3, the deposition mask MSK may include a base substrate BS, a first hard mask layer HM1, and inorganic layers including first inorganic layer IL1 and second inorganic layer IL2.

The base substrate BS may include silicon, but is not necessarily limited thereto. A first inorganic layer IL1 may be disposed on the base substrate BS. The base substrate BS may be an example of, or includes aspects of, the corresponding element described with reference to FIG. 2.

The first inorganic layer IL1 may be disposed on a first surface (or front surface) SB1, a second surface (or back surface) SB2, and a third surface (or side surface) SB3 of the base substrate BS. For example, the first inorganic layer IL1 may include a first region IL11 disposed on the first surface (or front surface) SB1 of the base substrate BS, a second region IL12 disposed on the second surface (or back surface) SB2 of the base substrate BS, and a third region IL13 disposed on the third surface (or side surface) SB3 of the base substrate BS. In some cases, for example, the first inorganic layer IL1 may partially surround the base substrate BS. In an embodiment, the first inorganic layer IL1 may include silicon oxide (SiOx), but is not necessarily limited thereto.

The first hard mask layer HM1 may be disposed on the first surface SB1 (or the front surface) of the base substrate BS. The first hard mask layer HM1 may be disposed on the first region IL11 of the first inorganic layer IL1. The first hard mask layer HM1 may prevent the first inorganic layer IL1 covering (or protecting) the third surface SB3 of the base substrate BS from being etched, thereby minimizing a phenomenon in which the edge of the base substrate BS fractures, for example, chipping defects. The first hard mask layer HM1 may include an amorphous carbon layer, but is not necessarily limited thereto. In some cases, the first hard mask layer HM1 may include a multilayer stack of amorphous carbon and metal nitride layers. The thickness of the first hard mask layer HM1 may be selectively varied based on the position of the first hard mask layer HM1, with thicker edge portions to further reinforce protection of the third surface SB3 of the base substrate BS. In some cases, the width of the first hard mask layer HM1 may be substantially the same as the width of the first region IL11 of the first inorganic layer IL1 measured in the first direction DR1.

A second inorganic layer IL2 may be disposed on the first inorganic layer IL1 and the first hard mask layer HM1. The second inorganic layer IL2 may be disposed on the first surface SB1, the second surface SB2, and the third surface SB3 of the base substrate BS. For example, the second inorganic layer IL2 may include a first region IL21 disposed on the first region IL11 of the first inorganic layer IL1 and the first hard mask layer HM1, a second region IL22 disposed on the second region IL12 of the first inorganic layer IL1, and a third region IL23 disposed on the third region IL13 of the first inorganic layer IL1. In some cases, the second inorganic layer IL2 may partially surround the first hard mask layer HM1 and the first inorganic layer IL1. In an embodiment, the second inorganic layer IL2 may include silicon nitride (SiNx), but is not necessarily limited thereto.

In an embodiment, the second inorganic layer IL2 may have a shape with partially etched edges. For example, the edges of the first region IL21 of the second inorganic layer IL2 may be partially etched, such that a width in a first direction DR1 of the first region IL21 of the second inorganic layer IL2 is smaller than a width in the first direction DR1 of the second region IL22 of the second inorganic layer IL2. The width in the first direction DR1 of the first region IL21 of the second inorganic layer IL2 may be less than a width in the first direction DR1 of the third region IL23 of the second inorganic layer IL2. In an embodiment, even though the first region IL21 of the second inorganic layer IL2 is partially etched, the third region IL23 of the second inorganic layer IL2 may remain unetched. Therefore, the third surface SB3 (or edge) of the base substrate BS can be protected during the process of manufacturing the deposition mask MSK. In some embodiments, the partial etching of the first region IL21 may form a tapered or stepped profile. In some embodiments, the etching depth of the first region IL21 may be selectively varied to adjust alignment tolerance between the cell openings OP1 and the opening patterns OP2.

The deposition mask MSK may include cell openings OP1 and opening patterns OP2. The cell openings OP1 may penetrate the first region IL21 of the second inorganic layer IL2 and the first hard mask layer HM1 in the third direction DR3. Accordingly, deposition material may be provided to the main substrate MSB through the cell openings OP1.

The opening patterns OP2 may overlap the cell openings OP1 in the third direction DR3. The opening patterns OP2 may penetrate the second region IL22 of the second inorganic layer IL2, the second region IL12 of the first inorganic layer IL1, the base substrate BS, and the first region IL11 of the first inorganic layer IL1 in the third direction DR3. Accordingly, deposition material may be provided to the main substrate MSB through the opening patterns OP2.

According to the embodiments described above, the third surface SB3 (or edge) of the base substrate BS may be covered by the first inorganic layer IL1 and the second inorganic layer IL2. Accordingly, a phenomenon in which an etching solution infiltrates during the manufacturing process of the deposition mask MSK and causes edge breakage of the base substrate BS, such as chipping defects, can be minimized. In addition, the first hard mask layer HM1 may further minimize edge breakage by shielding the first inorganic layer IL1 during etching, thereby preserving the integrity of the sidewall coverage.

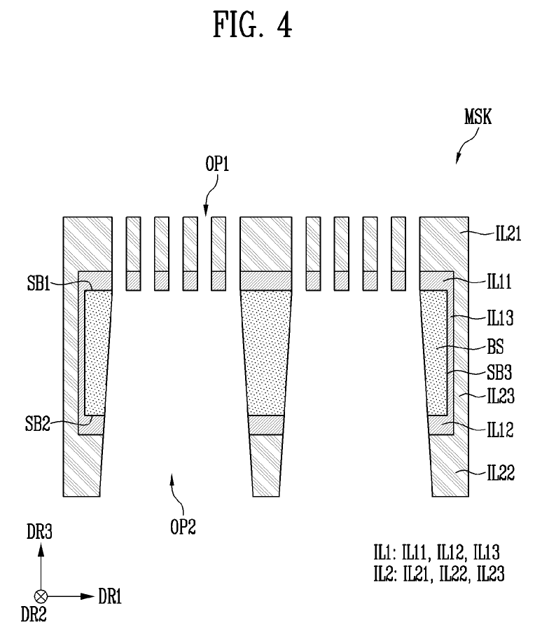

Referring to FIG. 4, the deposition mask MSK may include a base substrate BS and inorganic layers including first inorganic layer IL1 and second inorganic layer IL2.

The base substrate BS may include silicon, but is not necessarily limited thereto. A first inorganic layer IL1 may be disposed on the base substrate BS. The base substrate BS may be an example of, or includes aspects of, the corresponding element described with reference to FIG. 2.

The first inorganic layer IL1 may be disposed on a first surface (or front surface) SB1, a second surface (or back surface) SB2, and a third surface (or side surface) SB3 of the base substrate BS. For example, the first inorganic layer IL1 may include a first region IL11 disposed on the first surface (or front surface) SB1 of the base substrate BS, a second region IL12 disposed on the second surface (or back surface) SB2 of the base substrate BS, and a third region IL13 disposed on the third surface (or side surface) SB3 of the base substrate BS. In some cases, for example, the first inorganic layer IL1 may partially surround the base substrate BS. In an embodiment, the first inorganic layer IL1 may include silicon oxide (SiOx), but is not necessarily limited thereto.

A second inorganic layer IL2 may be disposed on the first inorganic layer IL1. The second inorganic layer IL2 may be disposed on the first surface SB1, the second surface SB2, and the third surface SB3 of the base substrate BS. For example, the second inorganic layer IL2 may include a first region IL21 disposed on the first region IL11 of the first inorganic layer IL1, a second region IL22 disposed on the second region IL12 of the first inorganic layer IL1, and a third region IL23 disposed on the third region IL13 of the first inorganic layer IL1. In some cases, for example, the second inorganic layer IL2 may partially surround the first inorganic layer IL1. In an embodiment, the second inorganic layer IL2 may include silicon nitride (SiNx), but is not necessarily limited thereto.

The deposition mask MSK may include cell openings OP1 and opening patterns OP2. The cell openings OP1 may penetrate the first region IL21 of the second inorganic layer IL2 and the first region IL11 of the first inorganic layer IL1 in the third direction DR3. Accordingly, deposition material may be provided to the main substrate MSB through the cell openings OP1. Compared to the cell openings OP1 described in FIG. 2, which penetrate the first region IL21 of the second inorganic layer IL2 in the third direction DR3, the cell openings OP1 penetrate first region IL21 of the second inorganic layer IL2 and the first region IL11 of the first inorganic layer IL1 in the third direction DR3.

The opening patterns OP2 may overlap the cell openings OP1 in the third direction DR3. The opening patterns OP2 may penetrate the second region IL22 of the second inorganic layer IL2, the second region IL12 of the first inorganic layer IL1, and the base substrate BS measured in the third direction DR3. Accordingly, deposition material may be provided to the main substrate MSB through the opening patterns OP2.

According to the embodiment described above, the third surface SB3 (or edge) of the base substrate BS may be covered by the first inorganic layer IL1 and the second inorganic layer IL2. Accordingly, a phenomenon in which an etching solution infiltrates during the manufacturing process of the deposition mask MSK and causes edge breakage of the base substrate BS, such as chipping defects, can be minimized.

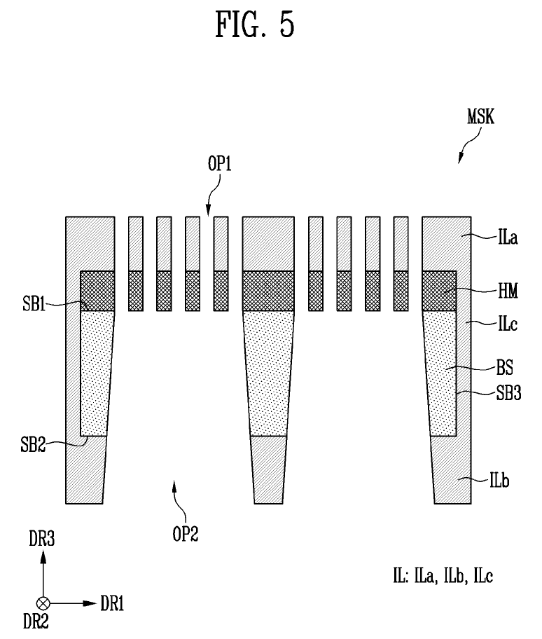

Referring to FIG. 5, the deposition mask MSK may include a base substrate BS, a hard mask layer HM, and an inorganic layer IL.

The base substrate BS may include, but is not necessarily limited to silicon. An inorganic layer IL may be disposed on the base substrate BS. The base substrate BS may be an example of, or includes aspects of, the corresponding element described with reference to FIG. 2.

The inorganic layer IL may be disposed on a first surface (or front surface) SB1, a second surface (or back surface) SB2, and a third surface (or side surface) SB3 of the base substrate BS. For example, the inorganic layer IL may include a first region ILa disposed on the first surface SB1 of the base substrate BS, a second region ILb disposed on the second surface SB2 of the base substrate BS, and a third region ILc disposed on the third surface SB3 of the base substrate BS. In some cases, for example, the inorganic layer IL may partially surround the base substrate BS. For example, the inorganic layer IL may surround three sides of the base substrate BS. In an embodiment, the inorganic layer IL may include silicon oxide (SiOx), but is not necessarily limited thereto.

The hard mask layer HM may be disposed on the first surface SB1 of the base substrate BS. The hard mask layer HM may be disposed under the first region ILa of the inorganic layer IL. For example, the hard mask layer HM may be disposed between the first region ILa of the inorganic layer IL and the first surface SB1 of the base substrate BS. The hard mask layer HM may include an amorphous carbon layer, but is not necessarily limited thereto.

The deposition mask MSK may include cell openings OP1 and opening patterns OP2. The cell openings OP1 may penetrate the first region ILa of the inorganic layer IL and the hard mask layer HM in the third direction DR3. For example, the cell openings OP1 may expose a side surface of the first region ILa of the inorganic layer IL and a side surface of the first surface SB1 of the base substrate BS. Thus, deposition material may be provided to the main substrate MSB through the cell openings OP1. In some embodiments, the cell openings OP1 may include circular, elliptical, or polygonal geometries configured to adjust deposition uniformity. In some embodiments, the cell openings OP1 may include tapered profiles.

The opening patterns OP2 may overlap the cell openings OP1 in the third direction DR3. The opening patterns OP2 may penetrate the second region ILb of the inorganic layer IL and the base substrate BS in the third direction DR3. For example, the opening patterns OP2 may expose a side surface of the second region ILb of the inorganic layer IL and a side surface of the base substrate BS. In some cases, the other side surface of the base substrate BS may be covered by the third region ILc of the inorganic layer IL. Accordingly, deposition material may be provided to the main substrate MSB through the opening patterns OP2. In one aspect, the opening patterns OP2 may be an example of, or includes aspects of, the corresponding element described with reference to FIGS. 2-4.

According to the embodiments described above, the third surface SB3 (or edge) of the base substrate BS may be covered by the inorganic layer IL. Accordingly, a phenomenon in which an etching solution infiltrates during the manufacturing process of the deposition mask MSK and causes edge breakage of the base substrate BS, such as chipping defects, can be minimized. In some embodiments, the hard mask layer HM disposed under the inorganic layer IL may further reinforce the protective coverage of the third surface SB3 by shielding the inorganic layer IL from etching damage.

Hereinafter, a display device and an electronic device including the display device manufactured using the MSK described with reference to FIGS. 2-5 are described.

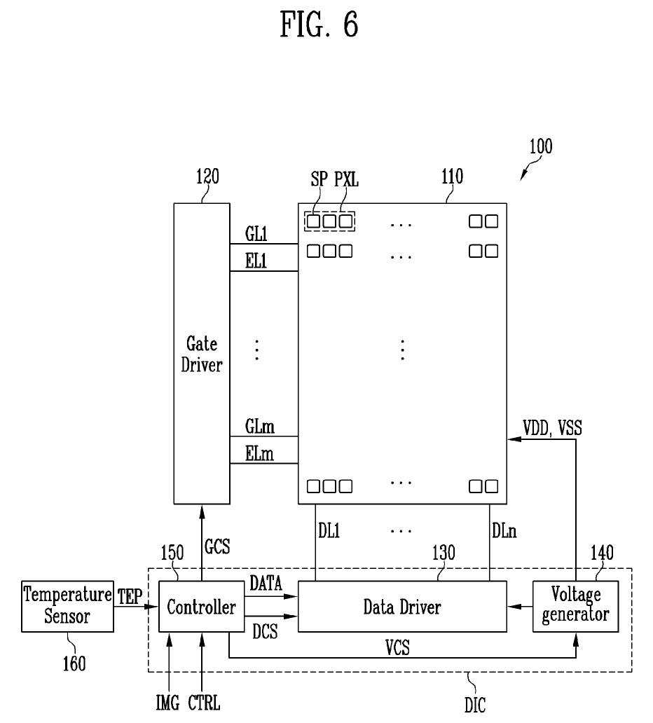

FIG. 6 is a block diagram illustrating a display device according to an embodiment of the present disclosure.

The display device 100 of FIG. 6 may be manufactured using the deposition mask MSK described above.

Referring to FIG. 6, the display device 100 may include a display panel 110, a gate driver 120, a data driver 130, a voltage generator 140, a controller 150, and a temperature sensor 160.

The display panel 110 may include sub-pixels SP. The sub-pixels SP may be connected to the gate driver 120 via first to m-th gate lines GL1 to GLm. The sub-pixels SP may be connected to the data driver 130 via first to n-th data lines DL1 to DLn.

Each of the sub-pixels SP may include at least one light-emitting element configured to generate light. Accordingly, each of the sub-pixels SP may generate light of a particular color, such as red, green, blue, cyan, magenta, or yellow. Two or more of the sub-pixels SP may form one pixel PXL. For example, as illustrated in FIG. 6, three sub-pixels SP may form as a single pixel PXL. In some embodiments, each pixel PXL may include four or more sub-pixels SP configured for advanced color generation or compensation functions, such as red, green, blue, and white (RGBW) arrangements or quantum-dot-enhanced emission sub-pixels.

The gate driver 120 may be coupled to the sub-pixels SP arranged in a row direction via the first to m-th gate lines GL1 to GLm. For example, m is a natural number greater than 1. The gate driver 120 may output gate signals to the first to m-th gate lines GL1 to GLm in response to a gate control signal GCS. In an embodiment, the gate control signal GCS may include a start signal to indicate a start of each frame, a horizontal synchronization signal to output gate signals in synchronization with a timing of data signals being applied, and other signals.

In an embodiment, first to m-th light emission control lines EL1 to ELm connected to sub-pixels SP in the row direction may be further provided. In such cases, the gate driver 120 may include a light emission control driver configured to control the first to m-th light emission control lines EL1 to ELm, and the light emission control driver may operate under control of the controller 150. In an embodiment, the light emission control driver may include a compensation circuit configured to adjust emission duration based on temperature data from a temperature sensor 160, thereby enhancing lifetime and luminance uniformity of the display panel 110.

The gate driver 120 may be located on one side of the display panel 110. However, embodiments are not necessarily limited thereto. For example, the gate driver 120 may be physically and/or logically separated into two or more drivers, and such drivers may be located on one side of the display panel 110 and on another side (or an opposite side) of the display panel 110. As such, the gate driver 120 may be located around the periphery of the display panel 110 in various configurations. In some embodiments, the gate driver 120 may be integrated directly onto the display panel 110 to reduce bezel size and improve integration.

The data driver 130 may be connected to the sub-pixels SP arranged in a column direction via first to n-th data lines DL1 to DLn. For example, n is a natural number greater than 1. In some cases, n and m are different numbers. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

Using voltages from the voltage generator 140, the data driver 130 may apply data signals having a grayscale voltage corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Accordingly, the corresponding sub-pixels SP may generate light corresponding to the data signals. Accordingly, the image may be displayed on the display panel 110. In some embodiments, the deposition mask MSK described herein may be configured to form sub-pixel emission layers within the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device 100. For example, the voltage generator 140 may be configured to generate one or more regulated voltages by receiving an external input voltage, performing voltage conversion, and outputting the converted voltage levels to the display device 100.

The voltage generator 140 may generate a first power voltage VDD and a second power voltage VSS, and the first and second power voltages VDD and VSS may be provided to the sub-pixels SP. The first power voltage VDD may have a relatively high voltage level, and the second power voltage VSS may have a lower voltage level than the first power voltage VDD. For example, the first power voltage VDD may be in a range of about 3.0V to about 12.0V. For example, the second power voltage VSS may correspond to a ground potential (e.g., 0V) or a negative voltage level such as –5.0V. In an embodiment, the first power voltage VDD or the second power voltage VSS may be provided by an external device to the display device 100.

In addition, the voltage generator 140 may generate various voltages. For example, the voltage generator 140 may generate an initialization voltage applied to the sub-pixels SP. For example, in a sensing operation for sensing electrical characteristics of transistors and/or light-emitting elements of the sub-pixels SP, a specific reference voltage may be applied to the first to n-th data lines DL1 to DLn, and the voltage generator 140 may generate a reference voltage. In an embodiment, the voltage generator 140 may generate compensation voltages dynamically adjusted based on a result of the sensing operation.

The controller 150 may control various operations of the display device 100. The controller 150 may receive input image data IMG and a control signal CTRL for controlling display of the image data IMG from an external device. In response to the control signal CTRL, the controller 150 may provide the gate control signal GCS, the data control signal DCS, and the voltage control signal VCS. For example, the controller 150 may provide the gate control signal GCS to the gate driver 120. The controller 150 may provide the data control signal DCS to the data driver 130. The controller 150 may provide the voltage control signal VCS to the voltage generator 140. In some embodiments, the controller 150 may further generate compensation control signals configured to adjust emission characteristics of the sub-pixels SP based on sensing feedback.

The controller 150 may convert the input image data IMG into a format suitable for driving the display device 100 or display panel 110 and output image data DATA. In an embodiment, the controller 150 may output the image data DATA by arranging the input image data IMG in a configuration or format suitable for addressing the sub-pixels SP on a row-by-row or column-by-column basis.

Two or more components among the data driver 130, the voltage generator 140, and the controller 150 may be mounted on a single integrated circuit. As shown in FIG. 6, the data driver 130, the voltage generator 140, and the controller 150 may be included in a driver integrated circuit DIC. In such cases, the data driver 130, the voltage generator 140, and the controller 150 may be functionally distinct components within the single driver integrated circuit DIC. In an embodiment, at least one among the data driver 130, the voltage generator 140, and the controller 150 may be provided as a component separate from the driver integrated circuit DIC.

The display device 100 may include at least one temperature sensor 160. The temperature sensor 160 may be configured to detect a temperature of the surroundings, and to generate temperature data TEP indicating the detected temperature. In an embodiment, the temperature sensor 160 may be disposed adjacent to the display panel 110 and/or the driver integrated circuit DIC. In some embodiments, the display device 100 may include multiple temperature sensors 160 arranged at different positions to monitor spatial temperature gradients across the display panel 110.

The controller 150 may control various operations of the display device 100 in response to the temperature data TEP. In an embodiment, the controller 150 may adjust brightness of an image output from the display panel 110 in response to temperature data TEP. For example, the controller 150 may adjust data signals and the first and second power voltages VDD and VSS by controlling components such as the data driver 130 and/or the voltage generator 140.

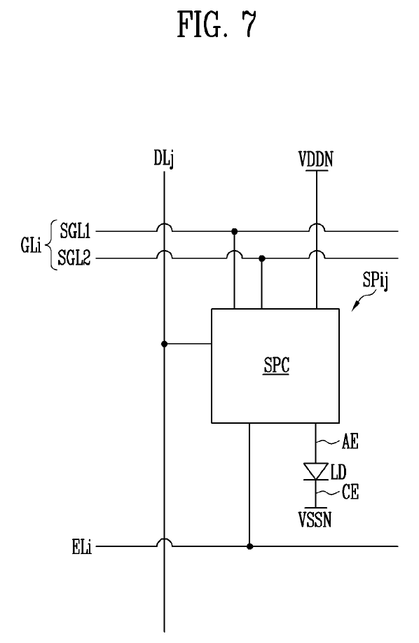

FIG. 7 is a block diagram illustrating a sub-pixel of the display device according to an embodiment of the present disclosure. In FIG. 7, a sub-pixel SPij arranged in an i-th row (where i is an integer greater than or equal to 1 and less than or equal to m) and a j-th column (where j is an integer greater than or equal to 1 and less than or equal to n) among the sub-pixels SP of FIG. 6 may be illustrated as an example.

Referring to FIG. 7, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node that delivers the first power voltage VDD in FIG. 6, and the second power voltage node VSSN may be a node that delivers the second power voltage VSS in FIG. 6. In some embodiments, the light-emitting element LD may be an organic light-emitting diode (OLED), a micro-OLED, or other types of emissive elements.

An anode electrode AE of the light-emitting element LD may be connected to the first power voltage node VDDN via the sub-pixel circuit SPC, and a cathode electrode CE of the light-emitting element LD may be connected to the second power voltage node VSSN. For example, the anode electrode AE of the light-emitting element LD may be connected to the first power voltage node VDDN via one or more transistors included in the sub-pixel circuit SPC.

The sub-pixel circuit SPC may be connected to an i-th gate line GLi of the first to m-th gate lines GL1 to GLm of FIG. 6, an i-th emission control line ELi of the first to m-th emission control lines EL1 to ELm of FIG. 6, and a j data line DLj of the first to n-th data lines DL1 to DLn of FIG. 6. The sub-pixel circuit SPC may be configured to control the light-emitting element LD in response to signals received via these signal lines.

The sub-pixel circuit SPC may operate in response to a gate signal received via the i-th gate line GLi. The i-th gate line GLi may include one or more sub-gate lines. In an embodiment, the i-th gate line GLi may include first and second sub-gate lines SGL1 and SGL2. The sub-pixel circuit SPC may operate in response to gate signals received via the first and second sub-gate lines SGL1 and SGL2. As such, when the i-th gate line GLi includes two or more sub gate lines, the sub-pixel circuit SPC may operate in response to gate signals received through those sub-gate lines.

The sub-pixel circuit SPC may operate in response to an emission control signal received via the i-th emission control line ELi. In an embodiment, the i-th emission control line ELi may include one or more sub-emission control lines. When the i-th light emission control line ELi includes two or more sub-emission control lines, the sub-pixel circuit SPC may operate in response to emission control signals received through those sub-emission control lines. In some embodiments, the multiple sub-emission control lines may be used to separately control initialization, emission, and compensation phases of the sub-pixel circuit SPC.

The sub-pixel circuit SPC may receive a data signal via the j-th data line DLj. The sub-pixel circuit SPC may store a voltage corresponding to the data signal in response to at least one of the gate signals received via the first and second sub-gate lines SGL1 and SGL2. In response to the emission control signal received via the i-th emission control line ELi, the sub-pixel circuit SPC may adjust the current flowing from the first power voltage node VDDN to the second power voltage node VSSN through the light-emitting element LD according to the stored voltage. Accordingly, the light-emitting element LD may generate light of a luminance corresponding to the data signal. In some embodiments, the sub-pixel circuit SPC may further include storage capacitors configured to hold the data signal voltage. In an embodiment, the sub-pixel circuit SPC may dynamically adjust driving current based on feedback signals.

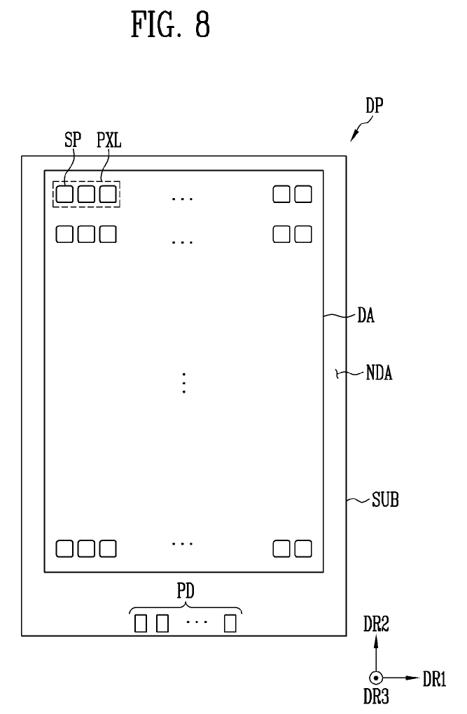

FIG. 8 is a plan view illustrating the display panel according to an embodiment of the present disclosure.

Referring to FIG. 8, an embodiment DP of the display panel 110 of FIG. 6 may include a display area DA and a non-display area NDA. The display panel DP may display an image through the display area DA. The non-display area NDA may be located around the display area DA.

The display panel DP may include a substrate SUB, sub-pixels SP, and pads PD.

In a case where the display panel DP is used as a display screen for a Head Mounted Display (HMD), a Virtual Reality (VR) device, a Mixed Reality (MR) device, or an Augmented Reality (AR) device, the display panel DP may be located very close to the eyes of a user. In these cases, the sub-pixels SP of high integration may be required. To increase the integration of the sub-pixels SP, the substrate SUB may be provided as a silicon substrate. On the substrate SUB, which is a silicon substrate, the sub-pixels SP and/or the display panel DP may be formed. The substrate SUB may correspond to the main substrate MSB in FIG. 1. The display device 100 including the display panel DP formed on the substrate SUB, which is a silicon substrate, may be referred to as an OLEDoS (OLED on Silicon) display device. In some embodiments, the substrate SUB may be implemented as a glass substrate, a quartz substrate, or a flexible (bendable) polymer substrate based on a target application. When a flexible substrate is used, the deposition mask MSK described above may facilitate high-resolution patterning by maintaining precise alignment and minimizing chipping defects at substrate edges.

The sub-pixels SP may be located in the display area DA on the substrate SUB. The sub-pixels SP may be arranged in a matrix form along a first direction DR1 and a second direction DR2 intersecting the first direction DR1. However, embodiments are not necessarily limited thereto. For example, the sub-pixels SP may be arranged in a zigzag shape along the first direction DR1 and the second direction DR2. For example, the sub-pixels SP may be arranged in a PENTILE^{TM} form. The first direction DR1 may be a row direction, and the second direction DR2 may be a column direction. Two or more sub-pixels of the sub-pixels SP may constitute as one pixel PXL. In some embodiments, each pixel PXL may include three sub-pixels configured for RGB operation. In some embodiments each pixel PXL may include four or more sub-pixels configured for RGBW or quantum-dot-based emission.

In the non-display area NDA on the substrate SUB, components for controlling the sub-pixels SP may be disposed. For example, wiring associated with the sub pixels SP, such as the first to m-th gate lines GL1 to GLm and the first to n-th data lines DL1 to DLn in FIG. 6, may be arranged in the non-display area NDA.

At least one among the gate driver 120, the data driver 130, the voltage generator 140, the controller 150, and the temperature sensor 160 of FIG. 6 may be integrated in the non-display area NDA of the display panel DP. In an embodiment, the gate driver 120 of FIG. 6 may be mounted on the display panel DP and located in the non-display area NDA. In an embodiment, the gate driver 120 may be implemented as an integrated circuit separate from the display panel DP. In an embodiment, the temperature sensor 160 may be placed in the non-display area NDA to detect a temperature of the display panel DP.

The pads PD may be located in the non-display area NDA on the substrate SUB. The pads PD may be electrically connected to the sub-pixels SP through wirings. For example, the pads PD may be connected to the sub-pixels SP via first to n-th data lines DL1 to DLn.

The pads PD may interface the display panel DP to other components of the display device 100. In an embodiment, voltages and signals required for operation of the components included in the display panel DP may be provided from a driver integrated circuit DIC of FIG. 6 through the pads PD. For example, the first to n-th data lines DL1 to DLn may be connected to the driver integrated circuit DIC via the pads PD. For example, the first and second power voltages VDD and VSS may be received from the driver integrated circuit DIC via the pads PD. For example, when the gate driver 120 is mounted on the display panel DP, a gate control signal GCS may be transmitted to the gate driver 120 via the pads PD from the driver integrated circuit DIC. In some embodiments, the pads PD may include redundant or enlarged contact structures to improve reliability and durability under repeated connection and disconnection cycles.

In an embodiment, a circuit board may be electrically connected to the pads PD using a conductive adhesive member such as an anisotropic conductive film. For example, the circuit board may be a flexible circuit board or a flexible film having a flexible material. The driver integrated circuit DIC may be mounted on the circuit board and electrically connected to the pads PD.

In an embodiment, the display area DA may have various shapes. The display area DA may have the shape of a closed loop including straight and/or curved sides. For example, the display area DA may have shapes such as a polygon, a circle, a semicircle, an ellipse, or other closed-loop geometries. In some embodiments, the display area DA may include openings or notches configured to accommodate external components such as cameras, sensors, or speakers.

In an embodiment, the display panel DP may have a flat display surface. In an embodiment, the display panel DP may have an at least partially rounded display surface. In an embodiment, the display panel DP may be bendable, foldable, or rollable. In such cases, the display panel DP and/or the substrate SUB may include materials having a flexible property.

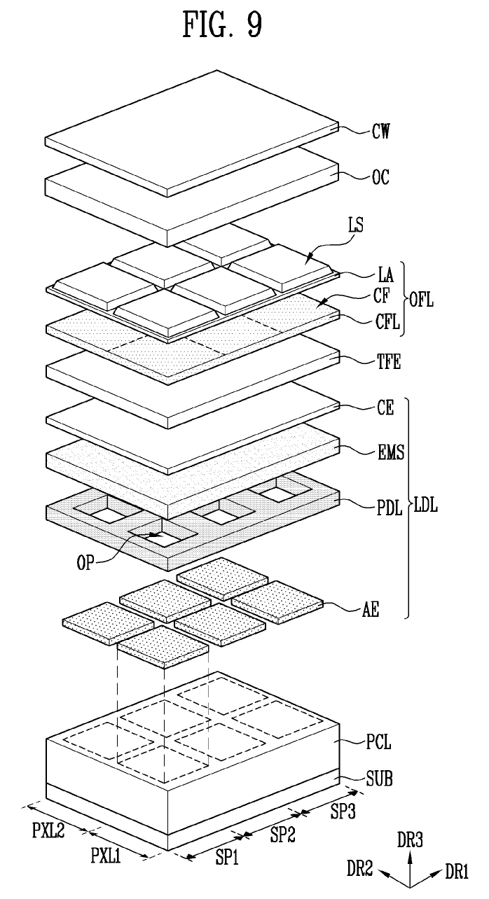

FIG. 9 is an exploded perspective view showing a portion of the display panel of FIG. 8.

Referring to FIGS. 8 and 9, each of the first and second pixels PXL1 and PXL2 may include first to third sub-pixels SP1 to SP3. However, the embodiments are not necessarily limited thereto. For example, each of the first and second pixels PXL1 and PXL2 may include four sub-pixels, or may include two sub-pixels.

In FIG. 9, the first to third sub-pixels SP1 to SP3 may be illustrated to have rectangular shapes and the same size when viewed in a third direction DR3 intersecting with the first and second directions DR1 and DR2. However, the embodiments are not necessarily limited to the aforementioned example. The first to third sub-pixels SP1 to SP3 may be modified to have various shapes. For example, the sub-pixels SP1 to SP3 may be implemented as triangular, hexagonal, or diamond shapes to optimize aperture ratio and improve pixel density in high-resolution applications.

The display panel DP may include a substrate SUB, a pixel circuit layer PCL, a light-emitting element layer LDL, an encapsulation layer TFE, an optical functional layer OFL, an overcoat layer OC, and a cover window CW. In some cases, additional barrier or adhesive layers may also be disposed between adjacent layers.

In an embodiment, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or other semiconductor-based substrates. In an embodiment, the substrate SUB may include a glass substrate. In an embodiment, the substrate SUB may include a polyimide (PI) substrate. In some embodiments, the substrate SUB may be implemented as a flexible or transparent substrate to support foldable displays or augmented reality (AR) devices.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least portions of the circuit components, lines, or other functional interconnects. The conductive patterns may include copper, but embodiments are not necessarily limited thereto. In some embodiments, the conductive patterns may include aluminum, silver, or transparent conductive oxides such as indium tin oxide (ITO).

The circuit elements may include respective sub-pixel circuits SPC (see FIG. 7) of the first to third sub-pixels SP1 to SP3. The sub-pixel circuit SPC may include transistors and one or more capacitors. Each transistor may include a semiconductor portion including a source area, a drain area, and a channel area, and a gate electrode overlapping the semiconductor portion. In an embodiment, when the substrate SUB is formed of a silicon substrate, the semiconductor portion may be included in the substrate SUB, and the gate electrode may be included in the pixel circuit layer PCL as a conductive pattern of the pixel circuit layer PCL. In an embodiment, when the substrate SUB is formed of a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined in the first and second directions DR1 and DR2. For example, each capacitor may include electrodes spaced apart from each other in the third direction DR3 with an insulating layer interposed therebetween. In some embodiments, the capacitors may include storage capacitors configured to store or maintain data voltages during a frame period.

The lines of the pixel circuit layer PCL may include signal lines connected to each of the first to third sub-pixels SP1 to SP3. For example, signal lines may be a gate line, an emission control line, and a data line. The lines may further include a line connected to the first power voltage node VDDN of FIG. 7. The lines may further include a line connected to the second power voltage node VSSN of FIG. 7. In some embodiments, the lines of the pixel circuit layer PCL may also include sensing lines configured to provide feedback signals to the controller 150.

The light-emitting element layer LDL may include anode electrodes AE, a pixel defining layer PDL, a light-emitting structure EMS, and a cathode electrode CE. In some embodiments, the light-emitting element layer LDL may further include buffer layers or charge injection layers disposed between the anode electrode AE, cathode electrode CE, and the light-emitting structure EMS.

The anode electrodes AE may be disposed on the pixel circuit layer PCL. The anode electrodes AE may be electrically connected to circuit elements of the pixel circuit layer PCL. The anode electrodes AE may include opaque conductive material capable of reflecting light, but embodiments are not necessarily limited thereto.

The pixel defining layer PDL may be disposed on the anode electrodes AE. The pixel defining layer PDL may include an opening OP that exposes a portion of each of the anode electrodes AE. The opening OP of the pixel defining layer PDL may be understood as an emission area corresponding to the first to third sub-pixels SP1 to SP3, respectively. In some embodiments, the openings OP may have tapered or rounded profiles to improve deposition uniformity of the light-emitting structure EMS.

In an embodiment, the pixel defining layer PDL may include inorganic material. For example, the pixel defining layer PDL may include a plurality of inorganic layers stacked on top of one another. For example, the pixel defining layer PDL may include silicon oxide (SiOx) and silicon nitride (SiNx). In an embodiment, the pixel defining layer PDL may include organic material. However, the material of the pixel defining layer PDL is not necessarily limited to the aforementioned examples. For example, the pixel defining layer PDL may include inorganic and organic layers.

The light-emitting structure EMS may be disposed on the anode electrodes AE exposed through the openings OP in the pixel defining layer PDL. In an embodiment, the cell openings OP1 of the deposition mask MSK may expose the opening OP of the pixel defining layer PDL, and the light-emitting structure EMS may be deposited on the opening OP of the pixel defining layer PDL using the deposition mask MSK. The light-emitting structure EMS may include a light-emitting layer configured to generate light, an electron transport layer configured to transport electrons, and a hole transport layer configured to transport holes. In an embodiment, portions of the light-emitting structure EMS corresponding to the first to third sub-pixels SP1 to SP3 may be separated from each other, and each separated light-emitting structure EMS may be disposed in the corresponding opening OP of the pixel defining layer PDL.

The cathode electrode CE may be disposed on the light-emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin-film metal layer having a thickness allowing light emitted from the light-emitting structure EMS to pass through the cathode electrode CE. The cathode electrode CE may be made of a metal material having a small thickness, or a transparent conductive material. In an embodiment, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In an embodiment, the cathode electrode CE may include at least one of silver (Ag), magnesium (Mg), and a compound thereof. However, the material of the cathode electrode CE is not necessarily limited to the aforementioned example. In some embodiments, the cathode electrode CE may include a multilayer structure including a thin metal layer and a transparent conductive oxide.

Any one of the anode electrodes AE, a portion of the light-emitting structure EMS overlapping the anode electrode AE, and a portion of the cathode electrode overlapping the light-emitting structure EMS may form as one light emitting element LD (see FIG. 7). For example, each of the light emitting elements of the first to third sub-pixels SP1 to SP3 may include one anode electrode, a portion of the light-emitting structure EMS overlapping anode electrode AE, and a portion of the cathode electrode CE overlapping the light-emitting structure. In each of the first to third sub-pixels SP1 to SP3, holes injected from the anode electrode AE and electrons injected from the cathode electrode CE are transported into the light-emitting layer of the light-emitting structure EMS, thus forming excitons. When the excitons transition from an excited state to a ground state, light can be generated. Depending on the amount of current flowing through the light-emitting layer, the luminance of light may be determined. Depending on the configuration of the light-emitting layer, the wavelength range of generated light may be determined. In some embodiments, the sub-pixels SP1, SP2, and SP3 may include light-emitting layers configured to emit red, green, and blue light, respectively.

The encapsulation layer TFE may be disposed on the cathode electrode CE. The encapsulation layer TFE may cover the light-emitting element layer LDL and/or the pixel circuit layer PCL. The encapsulation layer TFE may be configured to prevent oxygen and/or water from penetrating into the light-emitting element layer LDL. In an embodiment, the encapsulation layer TFE may include a structure formed by alternately stacking one or more inorganic layers and one or more organic layers. For example, the inorganic layer may include silicon nitride (SiNx), silicon oxide (SiOx), silicon oxynitride (SiOxNy), or other inorganic barrier materials. For example, the organic layer may include organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the encapsulation layer TFE are not necessarily limited thereto. In some embodiments, the encapsulation layer TFE may include flexible inorganic-organic multilayered structures to enable bending or folding of the display panel DP.

The optical functional layer OFL may be disposed on the encapsulation layer TFE. The optical functional layer OFL may include a color filter layer CFL and a lens layer LA.

The color filter layer CFL may be disposed between the encapsulation layer TFE and the lens layer LA. The color filter layer CFL may be configured to filter light emitted from the light-emitting structure EMS and selectively output light in a wavelength range or color corresponding to each sub-pixel. The color filter layer CFL may include color filters CF respectively corresponding to the first to third sub-pixels SP1 to SP3. Each of the color filters CF allows light within a wavelength range corresponding to the related sub-pixel to pass through the color filter CF. For example, the color filter that corresponds to the first sub-pixel SP1 allows light in a red color to pass, the color filter that corresponds to the second sub-pixel SP2 allows light in a green color to pass, and the color filter that corresponds to the third sub-pixel SP3 allows light in a blue color to pass. Based on the light emitted from the light-emitting structure EMS of each sub-pixel, at least some of the color filters CF may be omitted.

The lens layer LA may be disposed on the color filter layer CFL. The lens layer LA may include lenses LS that respectively correspond to the first to third sub-pixels SP1 to SP3. Each of the lenses LS may output and direct light emitted from the light-emitting structure EMS along an intended path, thus enhancing the light output efficiency. The lens layer LA may have a high refractive index. For example, the lens layer LA may have a higher refractive index than the overcoat layer OC. In an embodiment, the lenses LS may include organic material. In an embodiment, the lenses LS may include acrylic material. However, the material of the lenses LS is not necessarily limited to the aforementioned materials.

In an embodiment, compared to the opening OP of the pixel defining layer PDL, at least some of the color filters CF of the color filter layer CFL and at least some of the lenses LS of the lens layer LA may be shifted in a direction parallel to the plane defined in the first and second directions DR1 and DR2. For example, in a central area of the display area DA, the center of each color filter and the center of each lens may be aligned with the center of the corresponding opening OP of the pixel defining layer PDL. For example, in the central area of the display area DA, the opening OP of the pixel defining layer PDL may completely overlap the corresponding color filter of the color filter layer CFL and the corresponding lens of the lens layer LA. In an area adjacent to the non-display area NDA within the display area DA, the center of the color filter and the center of the lens may be shifted in a planar direction from the center of the corresponding opening OP of the pixel defining layer PDL when viewed in the third direction DR3. For example, in the area adjacent to the non-display area NDA within the display area DA, each opening OP of the pixel defining layer PDL may partially overlap the corresponding color filter of the color filter layer CFL and the corresponding lens LS of the lens layer LA. Accordingly, light emitted from the light-emitting structure EMS in the central portion of the display area DA may be efficiently output in the normal direction of the display surface. Light emitted from the light-emitting structure EMS around the perimeter of the display area DA may be efficiently output in a direction inclined at a certain angle with respect to the normal direction of the display surface. In some embodiments, the shift of the color filters CF and lenses LS may be adjusted to improve viewing angle uniformity or to reduce color mixing at the edges of the display panel DP.

The overcoat layer OC may be disposed on the lens layer LA. The overcoat layer OC may cover the optical functional layer OFL, the encapsulation layer TFE, the light-emitting structure EMS, and/or the pixel circuit layer PCL. The overcoat layer OC may include various materials suitable for protecting underlying layers from foreign substances such as dust, water, or other contaminants. For example, the overcoat layer OC may include at least one of an inorganic insulating layer and an organic insulating layer. For instance, the overcoat layer OC may include epoxy, but embodiments are not necessarily limited thereto. The overcoat layer OC may have a lower refractive index than the lens layer LA.

The cover window CW may be disposed on the overcoat layer OC. The cover window CW may be configured to protect underlying layers. The cover window CW may have a higher refractive index than the overcoat layer OC. The cover window CW may include glass, but embodiments are not necessarily limited thereto. For example, the cover window CW may be an encapsulation glass layer configured to protect components disposed under the cover window CW. In an embodiment, the display device 100 might not include the cover window CW.

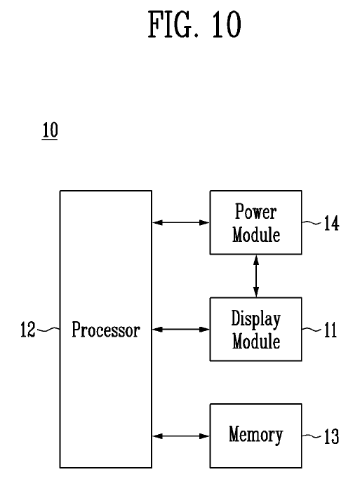

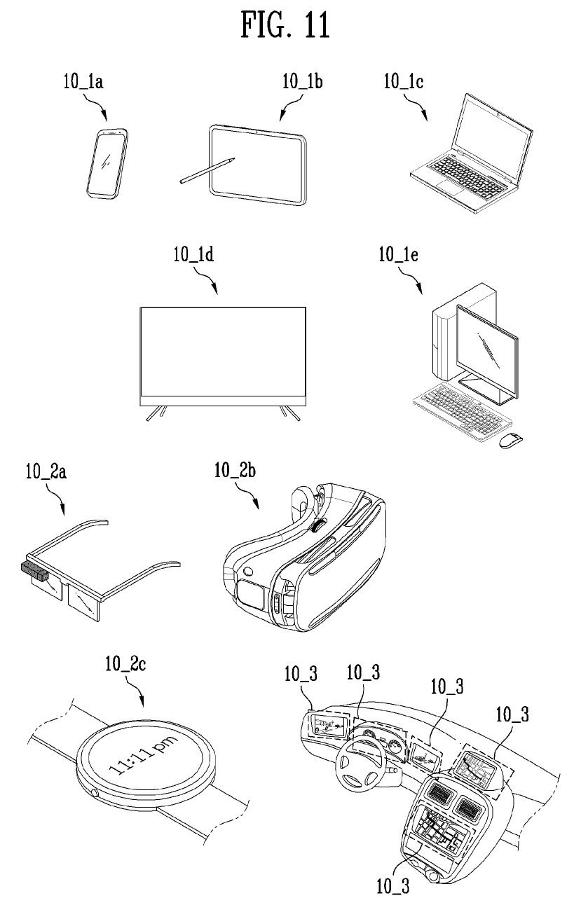

The display device 100 may be applied to various electronic devices. The electronic device includes the display device 100 described above, and may include one or more modules or devices having other additional functions in addition to the display device 100. Further detail on the electronic device is described with reference to FIG. 10. Further detail on the implementation of the electronic device is described with reference to FIG. 11.

FIG. 10 is a block diagram of an electronic device according to an embodiment of the present disclosure.

Referring to FIG. 10, the electronic device 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller. In some cases, the processor 12 may control the overall operation of the electronic device 10, including driving the display module 11 based on image and data signals stored in memory 13. The power module 14 may supply and control electrical power provided to each of the functional components.

The memory 13 may store data information for operating the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter, a battery device, or the like, and a power conversion module that converts power to operate the electronic device 10.

At least one of the above-described components of the electronic device 10 may be included in the display device 100. In addition, some parts of individual modules functionally included in one module may be included in the display device 100, and other modules may be included in a device other than the display device 100. For example, the display device 100 may include the display module 11, and the processor 12, the memory 13, and the power module 14 may be provided in other devices other than the display device 100.

FIG. 11 is a schematic diagram of an electronic device according to various embodiments of the present disclosure.

Referring to FIG. 11, various electronic devices 10 to which a display device 100 is applied may include an electronic device for displaying an image such as a smartphone 10_1a, a tablet computer 10_1b, a laptop computer 10_1c, a television (TV) 10_1d, and a computer monitor 10_1e. Various electronic devices 10 to which a display device 100 is applied may include a wearable electronic device including a display module such as smart glasses 10_2a, a head mounted display 10_2b, and a smart-watch 10_2c. Various electronic devices 10 to which a display device 100 is applied may include an automotive electronic device 10_3 including a display module, such as a CID (Center Information Display) disposed on an instrument panel, a center fascia, and a dashboard of a vehicle. Various electronic devices 10 to which a display device 100 is applied may include a room mirror display.

Next, a method for manufacturing a deposition mask according to the above-described embodiments is described.

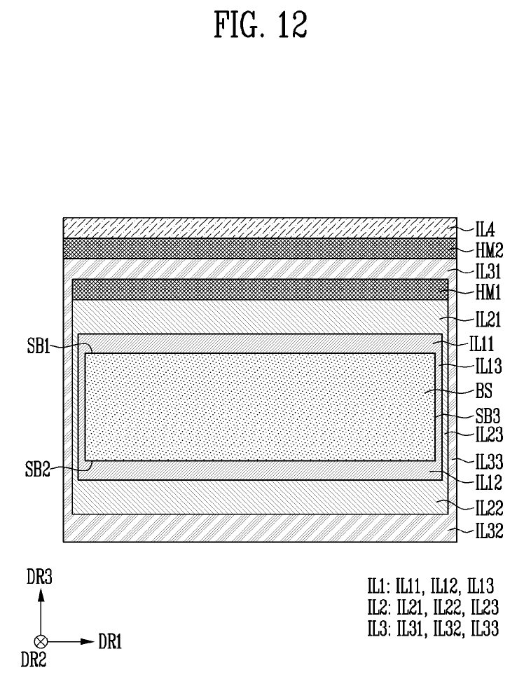

FIGS. 12-20 are cross-sectional views of process steps of a method for manufacturing a deposition mask according to an embodiment of the present disclosure. FIGS. 12-20 are cross-sectional views illustrating the method for manufacturing the deposition mask of FIG. 2.

Referring to FIG. 12, a base substrate BS is disposed, and a first inorganic layer IL1, a second inorganic layer IL2, a first hard mask layer HM1, a third inorganic layer IL3, a second hard mask layer HM2, and a fourth inorganic layer IL4 are sequentially formed on the base substrate BS.

A first region IL11 of the first inorganic layer IL1 may be formed on a first surface SB1 of the base substrate BS, a second region IL12 of the first inorganic layer IL1 may be formed on a second surface SB2 of the base substrate BS, and a third region IL13 of the first inorganic layer IL1 may be formed on a third surface SB3 of the base substrate BS. For example, the first inorganic layer IL1 may surround the base substrate BS. The first inorganic layer IL1 may be formed of silicon oxide (SiOx), but is not necessarily limited thereto.

A first region IL21 of the second inorganic layer IL2 may be formed on the first region IL11 of the first inorganic layer IL1, a second region IL22 of the second inorganic layer IL2 may be formed on the second region IL12 of the first inorganic layer IL1, and a third region IL23 of the second inorganic layer IL2 may be formed on the third region IL13 of the first inorganic layer IL1. For example, the second inorganic layer IL2 may surround the first inorganic layer IL1. The second inorganic layer IL2 may be formed of silicon nitride (SiNx), but is not necessarily limited thereto.

The first hard mask layer HM1 may be formed on the first region IL21 of the second inorganic layer IL2. For example, the first hard mask layer HM1 may overlap the first region IL21 of the second inorganic layer IL2. The first hard mask layer HM1 may prevent the inorganic layers IL1 and IL2 covering (or protecting) the third surface SB3 of the base substrate BS from being etched, thereby minimizing a phenomenon in which the edge of the base substrate BS breaks, for example, chipping defects. The first hard mask layer HM1 may include an amorphous carbon layer, but is not necessarily limited thereto.

A first region IL31 of the third inorganic layer IL3 may be formed on the first hard mask layer HM1, a second region IL32 of the third inorganic layer IL3 may be formed on the second region IL22 of the second inorganic layer IL2, and a third region IL33 of the third inorganic layer IL3 may be formed on the third region IL23 of the second inorganic layer IL2. In some cases, for example, the third region IL33 of the third inorganic layer IL3 may overlap a side surface of the first hard mask layer HM1 and the third region IL23 of the second inorganic layer IL2. In some cases, the third inorganic layer IL3 may surround the second inorganic layer IL2 and the first hard mask layer HM1. The third inorganic layer IL3 may be formed of silicon nitride (SiNx), but is not necessarily limited thereto.

The second hard mask layer HM2 may be formed on the first region IL31 of the third inorganic layer IL3. For example, the second hard mask layer HM2 may overlap the first region IL31 of the third inorganic layer IL3. The second hard mask layer HM2 may prevent the third inorganic layer IL3 covering (or protecting) the third surface SB3 of the base substrate BS from being etched, thereby minimizing a phenomenon in which the edge of the base substrate BS breaks, for example, chipping defects. The second hard mask layer HM2 may be an amorphous carbon layer, but is not necessarily limited thereto.

The fourth inorganic layer IL4 may be formed on the second hard mask layer HM2. For example, the fourth inorganic layer IL4 may overlap the second hard mask layer HM2 in the first direction. The fourth inorganic layer IL4 may be formed of silicon oxynitride (SiOxNy), but is not necessarily limited thereto.

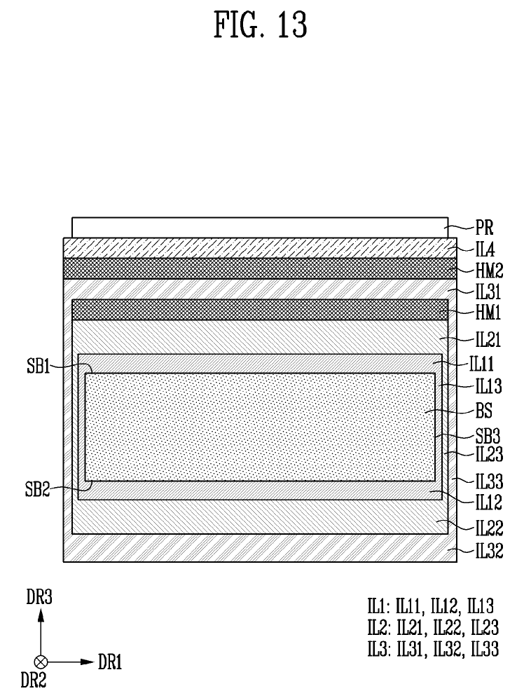

Referring to FIG. 13, a photoresist pattern PR is formed on the fourth inorganic layer IL4. The photoresist pattern PR may partially expose an edge of the fourth inorganic layer IL4. For example, after coating the photoresist pattern PR on the entire upper surface of the fourth inorganic layer IL4, the edges of the photoresist pattern PR may be partially removed. Accordingly, an edge of the fourth inorganic layer IL4 may be exposed through the photoresist pattern PR. As such, by partially removing the edge of the photoresist pattern PR, excessive thickening of the edge of the photoresist pattern PR can be prevented during the process of coating the photoresist pattern PR, or contamination caused by the photoresist pattern PR being deposited on the second surface SB2 or the third surface SB3 of the base substrate BS. In an embodiment, edge trimming of the photoresist pattern PR may be performed using plasma ashing or selective wet etching.

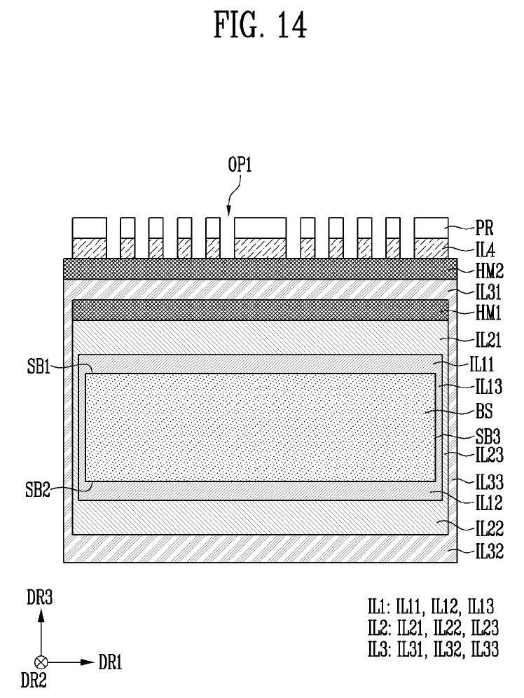

Referring to FIG. 14, the photoresist pattern PR is used as an etching mask, and the fourth inorganic layer IL4 is etched. Accordingly, cell openings OP1 may be formed through the photoresist pattern PR and into the fourth inorganic layer IL4. The cell openings OP1 may be formed in the fourth inorganic layer IL4, and edges of the fourth inorganic layer IL4 may be etched and removed.

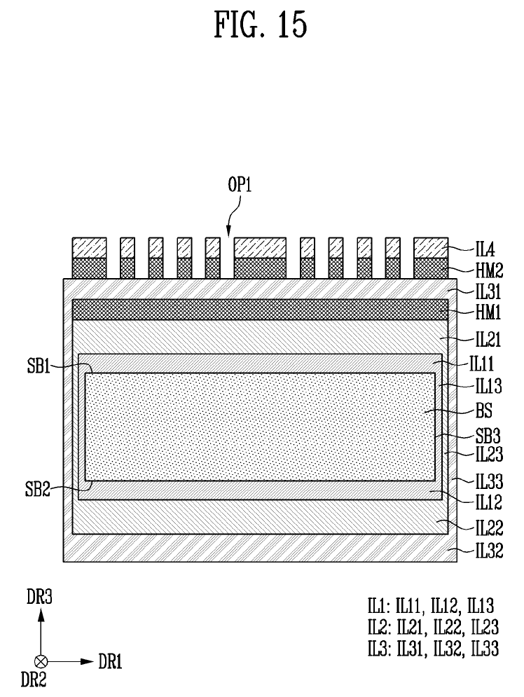

Referring to FIG. 15, the photoresist pattern PR is removed, and the second hard mask layer HM2 is etched. Accordingly, cell openings OP1 may be formed in the second hard mask layer HM2, and edges of the second hard mask layer HM2 may be etched and removed.

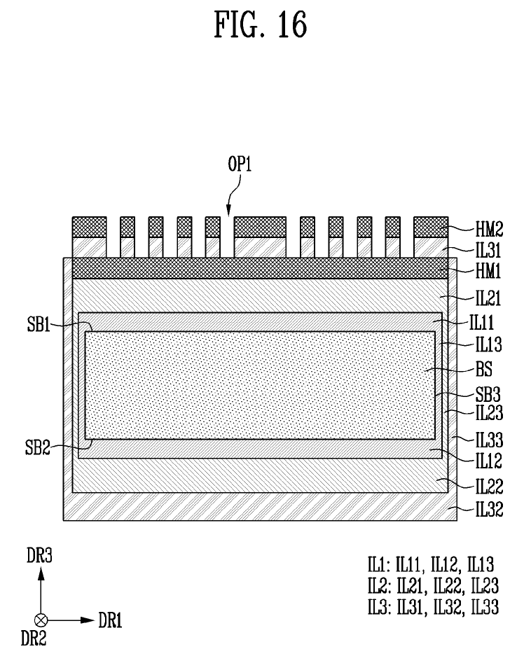

Referring to FIG. 16, the first region IL31 of the third inorganic layer IL3 is etched. Accordingly, cell openings OP1 may be formed in the first region IL31 of the third inorganic layer IL3, and edges of the first region IL31 of the third inorganic layer IL3 may be etched and removed. In an embodiment, in the process of etching the first region IL31 of the third inorganic layer IL3, the fourth inorganic layer IL4 may be etched and removed. For example, the etching of the first region IL31 of the third inorganic layer IL3 may simultaneously remove at least portions of the fourth inorganic layer IL4 disposed above the second hard mask layer HM2. The use of the second hard mask layer HM2 during this process provides etching selectivity and process stability, reducing damage to adjacent regions.

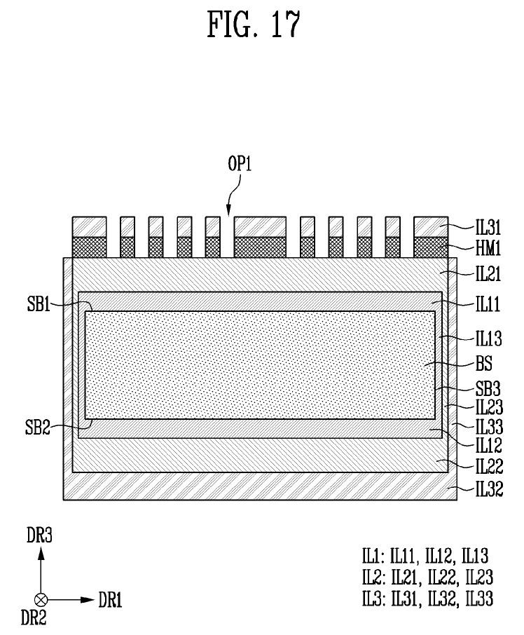

Referring to FIG. 17, the first hard mask layer HM1 is ashed. Accordingly, cell openings OP1 may be formed in the first hard mask layer HM1, and edges of the first hard mask layer HM1 may be etched and removed. In an embodiment, in the process of ashing the first hard mask layer HM1, the second hard mask layer HM2 may be ashed and removed. For example, the ashing of the first hard mask layer HM1 may simultaneously result in removal of the second hard mask layer HM2 formed above the third inorganic layer IL3.

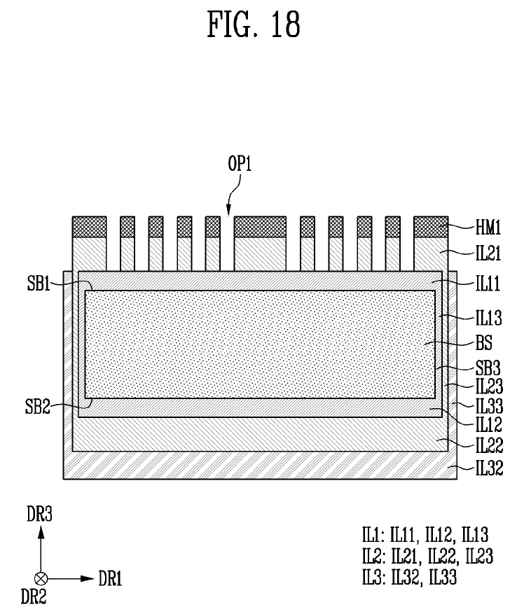

Referring to FIG. 18, the first region IL21 of the second inorganic layer IL2 is etched. Accordingly, cell openings OP1 are formed in the first region IL21 of the second inorganic layer IL2, and edges of the first region IL21 of the second inorganic layer IL2 may be etched and removed. In an embodiment, in the process of etching the first region IL21 of the second inorganic layer IL2, the first region IL31 of the third inorganic layer IL3 may be etched and removed. For example, the etching of the first region IL21 of the second inorganic layer IL2 may simultaneously remove at least portions of the first region IL31 of the third inorganic layer IL3 disposed above the first hard mask layer HM1.

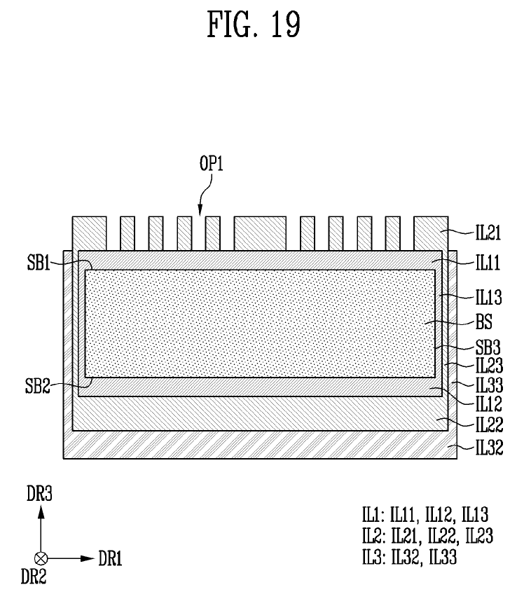

Referring to FIG. 19, the first hard mask layer HM1 is removed by ashing. For example, the first region IL21 of the second inorganic layer IL2 may remain on the first inorganic layer IL1, and may define the cell openings OP1.

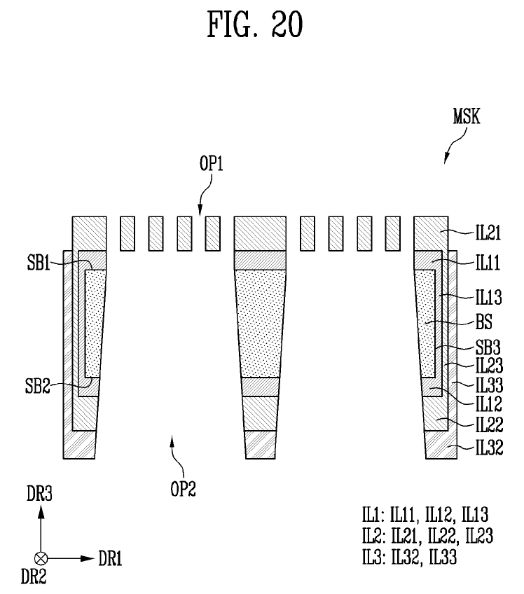

Referring to FIG. 20, the second region IL32 of the third inorganic layer IL3, the second region IL22 of the second inorganic layer IL2, the second region IL12 of the first inorganic layer IL1, the base substrate BS, and the first region IL11 of the first inorganic layer IL1 are etched to form opening patterns OP2. During this step, the tapered profiles of OP2 enable efficient deposition material transfer, while maintaining structural integrity of the mask MSK. In the process of forming the opening patterns OP2, the third surface SB3 (or edge) of the base substrate BS may be covered by the first inorganic layer IL1, the second inorganic layer IL2, and the third inorganic layer IL3. Accordingly, a phenomenon in which an etching solution infiltrates during the manufacturing process of the deposition mask MSK and causes edge breakage of the base substrate BS, such as chipping defects, can be minimized.

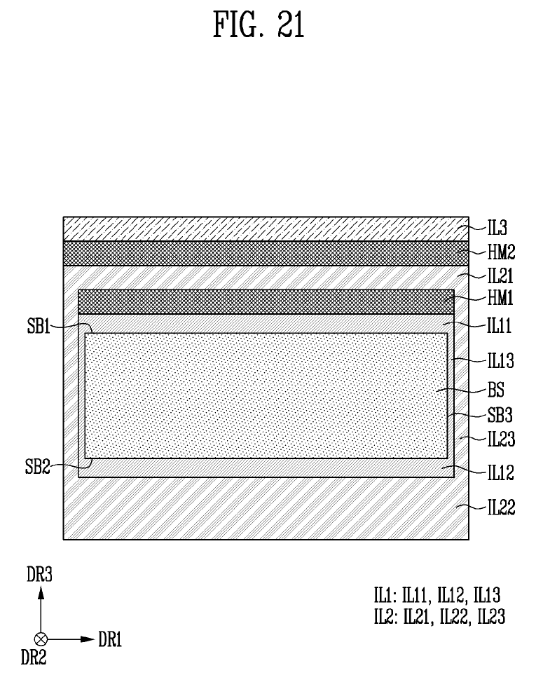

FIGS. 21-27 are cross-sectional views of process steps of a method for manufacturing a deposition mask according to an embodiment of the present disclosure. FIGS. 21-27 are cross-sectional views for illustrating the method for manufacturing the deposition mask of FIG. 3.

Referring to FIG. 21, a base substrate BS is disposed, and a first inorganic layer IL1, a first hard mask layer HM1, a second inorganic layer IL2, a second hard mask layer HM2, and a third inorganic layer IL3 are sequentially formed on the base substrate BS.

A first region IL11 of the first inorganic layer IL1 may be formed on a first surface SB1 of the base substrate BS, a second region IL12 of the first inorganic layer IL1 may be formed on a second surface SB2 of the base substrate BS, and a third region IL13 of the first inorganic layer IL1 may be formed on a third surface SB3 of the base substrate BS. For example, the first inorganic layer IL1 may surround the base substrate BS. The first inorganic layer IL1 may be formed of silicon oxide (SiOx), but is not necessarily limited thereto.

The first hard mask layer HM1 may be formed on the first region IL11 of the first inorganic layer IL1. For example, the first hard mask layer HM1 may overlap the first region IL11 of the first inorganic layer IL1. The first hard mask layer HM1 may prevent the first inorganic layer IL1 covering (or protecting) the third surface SB3 of the base substrate BS from being etched, thereby minimizing a phenomenon in which the edge of the base substrate BS breaks, for example, chipping defects. The first hard mask layer HM1 may include an amorphous carbon layer, but is not necessarily limited thereto.

A first region IL21 of the second inorganic layer IL2 may be formed on the first hard mask layer HM1, a second region IL22 of the second inorganic layer IL2 may be formed on the second region IL12 of the first inorganic layer IL1, and a third region IL23 of the second inorganic layer IL2 may be formed on the third region IL13 of the first inorganic layer IL1. In some cases, for example, the third region IL23 of the second inorganic layer IL2 may overlap a side surface of the first hard mask layer HM1 and the third region IL13 of the first inorganic layer IL1. In some cases, the second inorganic layer IL2 may surround the first inorganic layer IL1 and the first hard mask layer HM1. The second inorganic layer IL2 may be formed of silicon nitride (SiNx), but is not necessarily limited thereto.

The second hard mask layer HM2 may be formed on the first region IL21 of the second inorganic layer IL2. For example, the second hard mask layer HM2 may overlap the first region IL21 of the second inorganic layer IL2. The second hard mask layer HM2 may prevent the second inorganic layer IL2 covering (or protecting) the third surface SB3 of the base substrate BS from being etched, thereby minimizing a phenomenon in which the edge of the base substrate BS breaks, for example, chipping defects. The second hard mask layer HM2 may be an amorphous carbon layer, but is not necessarily limited thereto.

The third inorganic layer IL3 may be formed on the second hard mask layer HM2. For example, the third inorganic layer IL3 may overlap the second hard mask layer HM2 in the first direction. The third inorganic layer IL3 may be formed of silicon oxynitride (SiOxNy) but is not necessarily limited thereto.

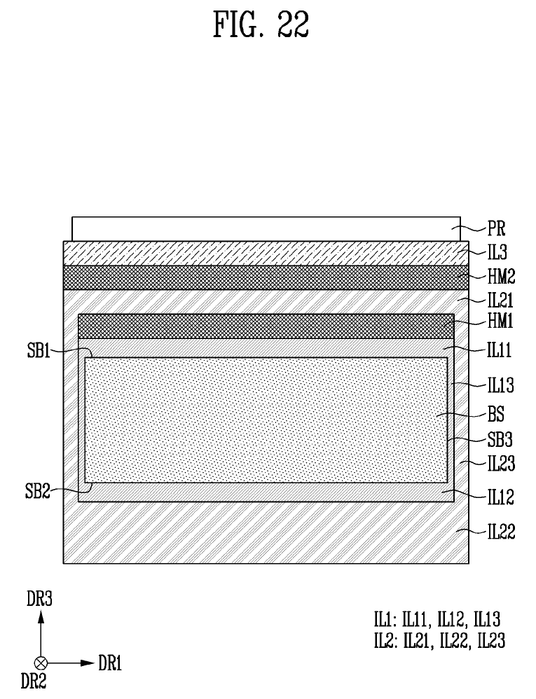

Referring to FIG. 22, a photoresist pattern PR is formed on the third inorganic layer IL3. The photoresist pattern PR may partially expose an edge of the third inorganic layer IL3. For example, after coating the photoresist pattern PR on the entire upper surface of the third inorganic layer IL3, the edge of the photoresist pattern PR may be partially removed. Accordingly, an edge of the third inorganic layer IL3 may be exposed through the photoresist pattern PR. As such, by partially removing the edge of the photoresist pattern PR, excessive thickening of the edge of the photoresist pattern PR can be prevented during the process of coating the photoresist pattern PR, or contamination caused by the photoresist pattern PR being deposited on the second surface SB2 or the third surface SB3 of the base substrate BS. In an embodiment, edge trimming of the photoresist pattern PR may be performed using plasma ashing or selective wet etching.

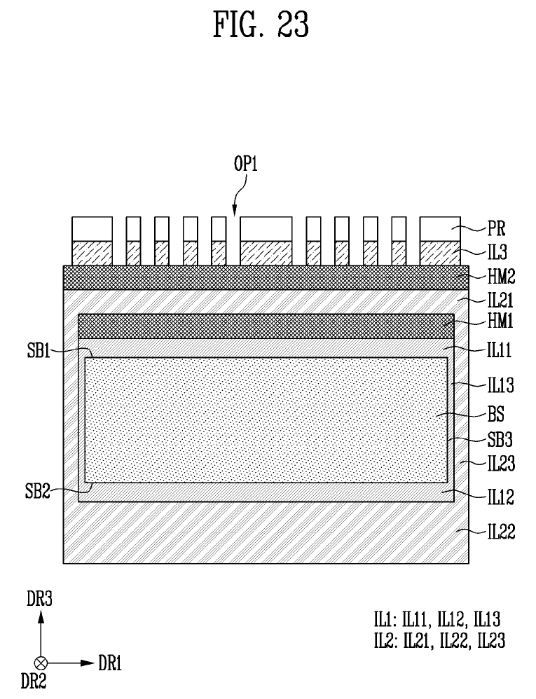

Referring to FIG. 23, the photoresist pattern PR is used as an etching mask, and the third inorganic layer IL3 is etched. Accordingly, cell openings OP1 may be formed through the photoresist pattern PR and into the third inorganic layer IL3. The cell openings OP1 may be formed in the third inorganic layer IL3, and edges of the third inorganic layer IL3 may be etched and removed.

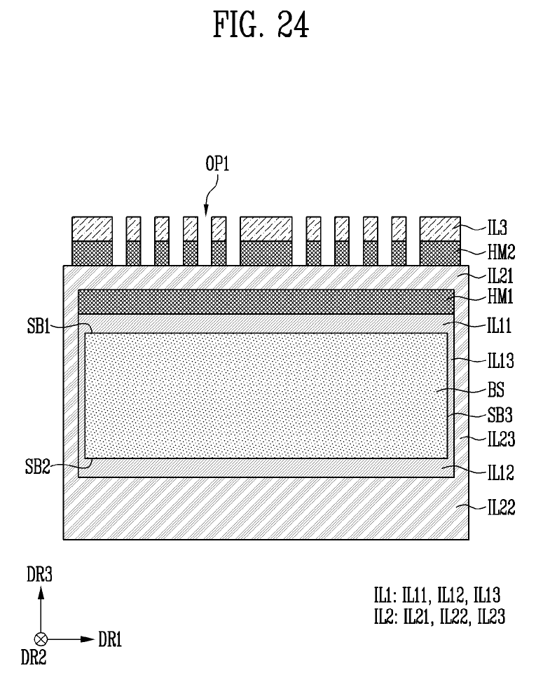

Referring to FIG. 24, the photoresist pattern PR is removed, and the second hard mask layer HM2 is etched. Accordingly, the cell openings OP1 may be formed in the second hard mask layer HM2, and edges of the second hard mask layer HM2 may be etched and removed.

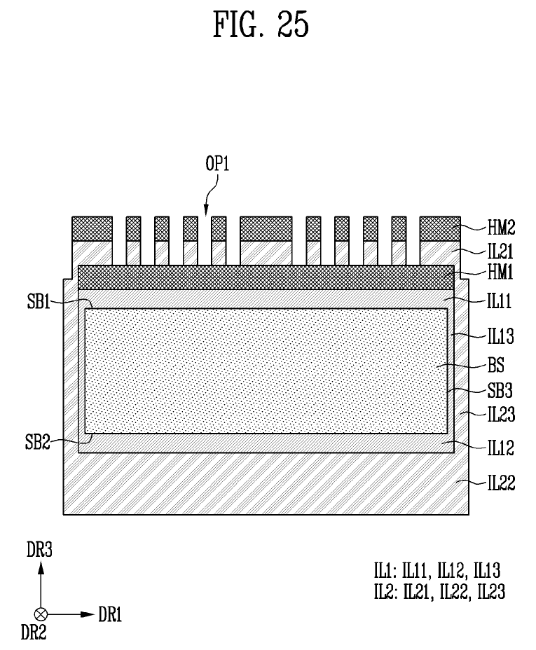

Referring to FIG. 25, the first region IL21 of the second inorganic layer IL2 is etched. Accordingly, cell openings OP1 may be formed in the first region IL21 of the second inorganic layer IL2, and an edge of the first region IL21 of the second inorganic layer IL2 may be etched and removed. In an embodiment, a width measured in the first direction DR1 of the first region IL21 of the second inorganic layer IL2 may be formed smaller than a width measured in the first direction DR1 of the second region IL22 of the second inorganic layer IL2. The width measured in the first direction DR1 of the first region IL21 of the second inorganic layer IL2 may be formed smaller than a width measured in the first direction DR1 of the third region IL23 of the second inorganic layer IL2. Even though the first region IL21 of the second inorganic layer IL2 is partially etched, the third region IL23 of the second inorganic layer IL2 might not be etched. Thus, the third surface SB3 (or edge) of the base substrate BS can be protected during the process of manufacturing the deposition mask MSK. In an embodiment, during the process of etching the first region IL21 of the second inorganic layer IL2, the third inorganic layer IL3 may be etched and removed.

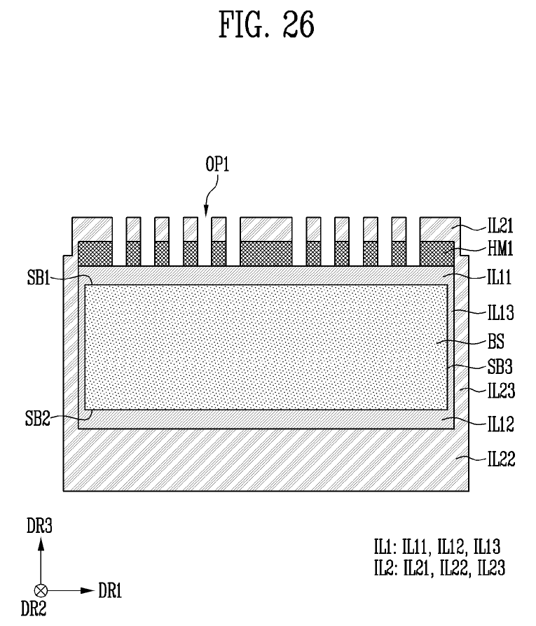

Referring to FIG. 26, the first hard mask layer HM1 is ashed. Accordingly, cell openings OP1 may be formed in the first hard mask layer HM1. In an embodiment, in the process of ashing the first hard mask layer HM1, the second hard mask layer HM2 may be ashed and removed. For example, the ashing of the first hard mask layer HM1 may simultaneously result in removal of the second hard mask layer HM2 formed above the second inorganic layer IL2.

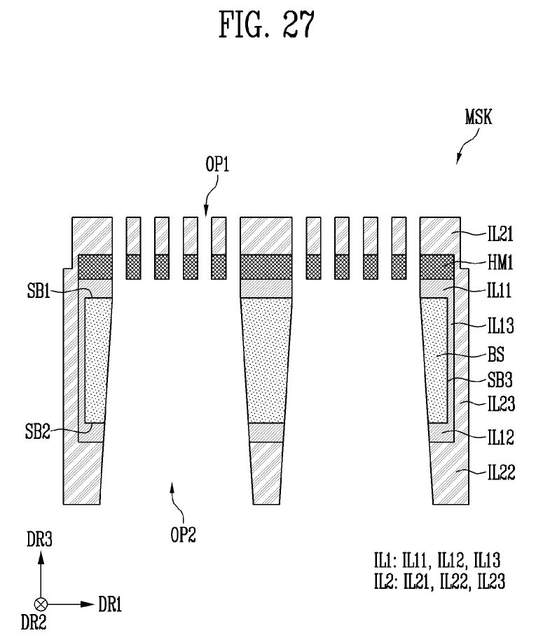

Referring to FIG. 27, the second region IL22 of the second inorganic layer IL2, the second region IL12 of the first inorganic layer IL1, the base substrate BS, and the first region IL11 of the first inorganic layer IL1 are etched to form opening patterns OP2. In the process of forming the opening patterns OP2, the third surface SB3 (or edge) of the base substrate BS may be covered by the first inorganic layer IL1 and the second inorganic layer IL2. Accordingly, a phenomenon in which an etching solution infiltrates during the manufacturing process of the deposition mask MSK and causes edge breakage of the base substrate BS, such as chipping defects, can be minimized.

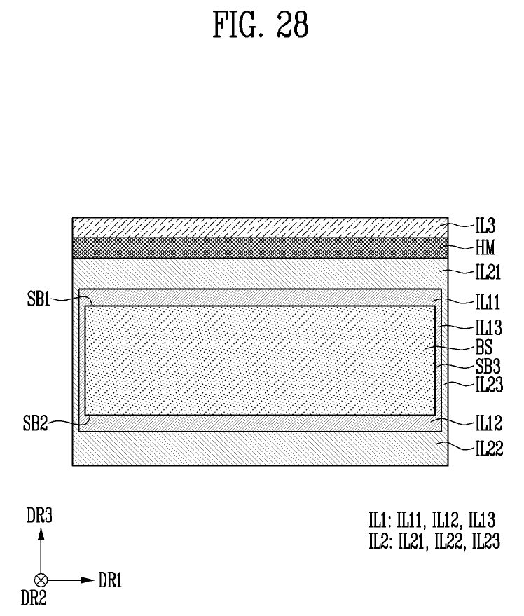

FIGS. 28-32 are cross-sectional views of process steps of a method for manufacturing a deposition mask according to an embodiment of the present disclosure. FIGS. 28-32 are cross-sectional views to illustrate the method for manufacturing the deposition mask of FIG. 4.

Referring to FIG. 28, a base substrate BS is disposed, and a first inorganic layer IL1, a second inorganic layer IL2, a hard mask layer HM, and a third inorganic layer IL3 are sequentially formed on the base substrate BS.

A first region IL11 of the first inorganic layer IL1 may be formed on a first surface SB1 of the base substrate BS, a second region IL12 of the first inorganic layer IL1 may be formed on a second surface SB2 of the base substrate BS, and a third region IL13 of the first inorganic layer IL1 may be formed on a third surface SB3 of the base substrate BS. For example, the first inorganic layer IL1 may surround the base substrate BS. The first inorganic layer IL1 may be formed of silicon oxide (SiOx), but is not necessarily limited thereto.

A first region IL21 of the second inorganic layer IL2 may be formed on the first region IL11 of the first inorganic layer IL1, a second region IL22 of the second inorganic layer IL2 may be formed on the second region IL12 of the first inorganic layer IL1, and a third region IL23 of the second inorganic layer IL2 may be formed on the third region IL13 of the first inorganic layer IL1. For example, the second inorganic layer IL2 may surround the first inorganic layer IL1. The second inorganic layer IL2 may be formed of silicon nitride (SiNx), but is not necessarily limited thereto.

A hard mask layer HM may be formed on the first region IL21 of the second inorganic layer IL2. For example, the hard mask layer HM may overlap the first region IL21 of the second inorganic layer IL2. The hard mask layer HM may prevent the inorganic layers IL1 and IL2 covering (or protecting) the third surface SB3 of the base substrate BS from being etched, thereby minimizing a phenomenon in which the edge of the base substrate BS breaks, for example, chipping defects. The hard mask layer HM may include chromium (Cr), tungsten (W), molybdenum (Mo), or titanium nitride (TiN), but is not necessarily limited thereto.

The third inorganic layer IL3 may be formed on the hard mask layer HM. The third inorganic layer IL3 may be formed of silicon oxynitride (SiOxNy), but is not necessarily limited thereto. In some cases the third inorganic layer IL3 and the hard mask layer HM may substantially overlap an upper surface of the second inorganic layer IL2.

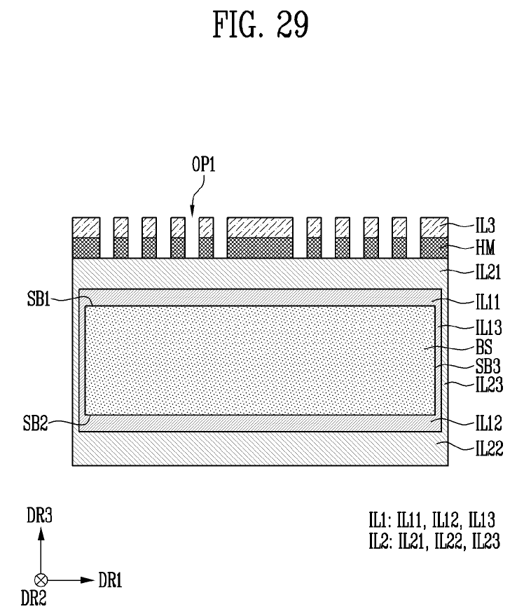

Referring to FIG. 29, the third inorganic layer IL3 and the hard mask layer HM are patterned to form cell openings OP1 in the third inorganic layer IL3 and the hard mask layer HM.

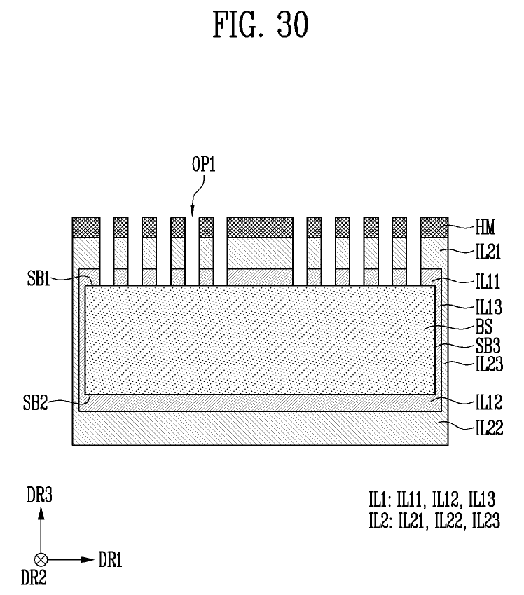

Referring to FIG. 30, the first region IL21 of the second inorganic layer IL2 and the first region IL11 of the first inorganic layer IL1 are etched. Accordingly, cell openings OP1 may be formed in the first region IL21 of the second inorganic layer IL2 and the first region IL11 of the first inorganic layer IL1. In the process of etching the first region IL21 of the second inorganic layer IL2 and the first region IL11 of the first inorganic layer IL1, the third inorganic layer IL3 may be etched and removed. For example, etching the first region IL21 of the second inorganic layer IL2 and the first region IL11 of the first inorganic layer IL1 may simultaneously result in removal of the third inorganic layer IL3 formed above the hard mask layer.

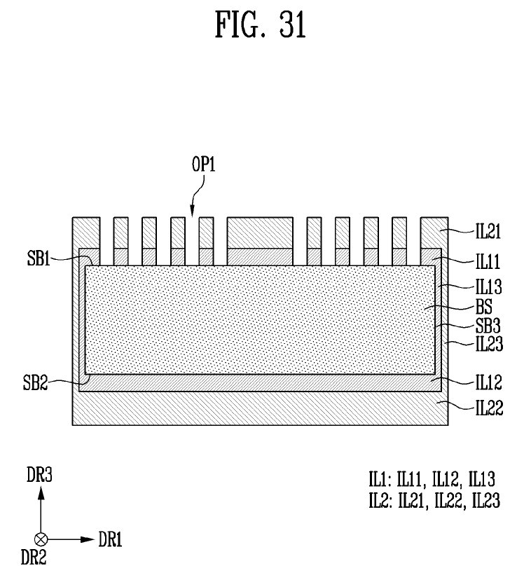

Referring to FIG. 31, the hard mask layer HM is then etched and removed.

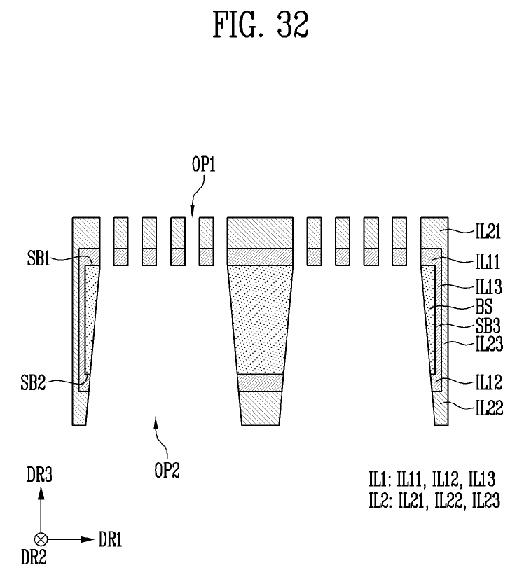

Referring to FIG. 32, the second region IL22 of the second inorganic layer IL2, the second region IL12 of the first inorganic layer IL1, and the base substrate BS are etched to form opening patterns OP2. In the process of forming the opening patterns OP2, the third surface SB3 (or edge) of the base substrate BS may be covered by the first inorganic layer IL1 and the second inorganic layer IL2. Accordingly, a phenomenon in which an etching solution infiltrates during the manufacturing process of the deposition mask MSK and causes edge breakage of the base substrate BS, such as chipping defects, can be minimized.

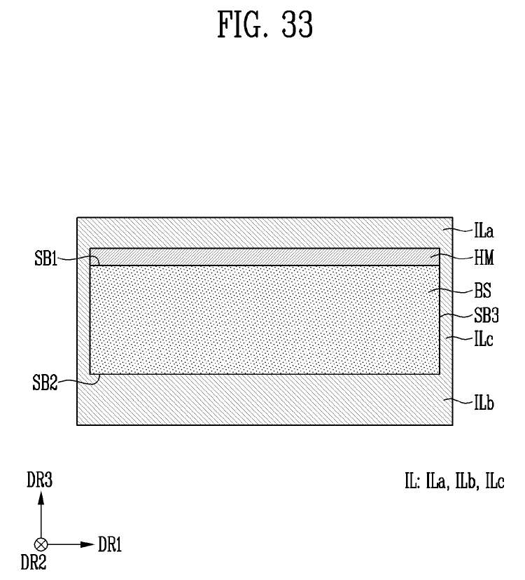

FIGS. 33-36 are cross-sectional views of process steps of a method for manufacturing a deposition mask according to an embodiment of the present disclosure. FIGS. 33-36 are cross-sectional views to illustrate the method for manufacturing the deposition mask of FIG. 5.

Referring to FIG. 33, a base substrate BS is disposed, and a hard mask layer HM and an inorganic layer IL are sequentially formed on the base substrate BS.

The hard mask layer HM may be formed on a first surface SB1 of the base substrate BS. For example, the hard mask layer HM may be disposed on the first surface SB1 of the base substrate BS. The hard mask layer HM may include chromium (Cr), tungsten (W), molybdenum (Mo), and titanium nitride (TiN), but is not necessarily limited thereto.

A first region ILa of the inorganic layer IL may be formed on the hard mask layer HM, a second region ILb of the inorganic layer IL may be formed on a second surface SB2 of the base substrate BS, and a third region ILc of the inorganic layer IL may be formed on a third surface SB3 of the base substrate BS. For example, the inorganic layer IL may surround the hard mask layer HM and the base substrate BS. The inorganic layer IL may be formed of silicon oxide (SiOx), but is not necessarily limited thereto.

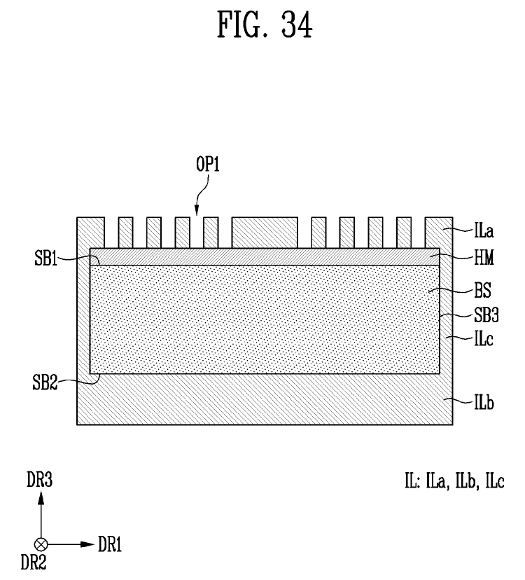

Referring to FIG. 34, the first region ILa of the inorganic layer IL is patterned to form cell openings OP1 in the first region ILa of the inorganic layer IL.

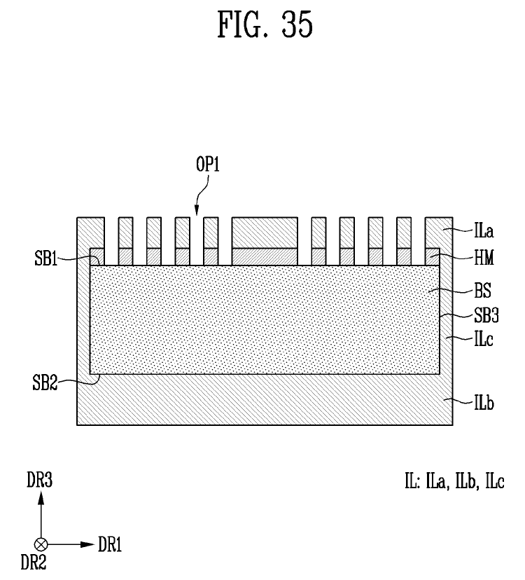

Referring to FIG. 35, the hard mask layer HM is etched to form the cell openings OP1 in the hard mask layer HM. For example, the cell openings OP1 may expose side surfaces of the first region Ila and side surfaces of the hard mask layer HM.

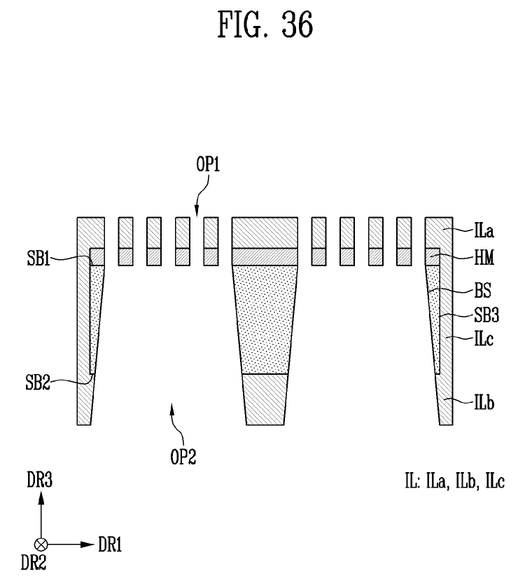

Referring to FIG. 36, the second region ILb of the inorganic layer IL and the base substrate BS are etched to form opening patterns OP2. In the process of forming the opening patterns OP2, the third surface SB3 (or edge) of the base substrate BS may be covered by the inorganic layer IL. Accordingly, a phenomenon in which an etching solution infiltrates during the manufacturing process of the deposition mask MSK and causes edge breakage of the base substrate BS, such as chipping defects, can be minimized.

In the detailed description, those skilled in the art will appreciate that many variations and modifications can be made to the preferred embodiments without substantially departing from the technical scope and principles of the present inventive concept. .

What is claimed is:

1. A deposition mask, comprising:
a first inorganic layer including a first region disposed on a first surface of a base substrate, a second region disposed on a second surface of the base substrate, and a third region disposed on a third surface of the base substrate, wherein the first surface and the second surface are major surfaces of the base substrate and the third surface is a minor surface of the base substrate;
cell openings penetrating the first region of the first inorganic layer; and
opening patterns penetrating the second region of the first inorganic layer and the base substrate, wherein the opening patterns overlap the cell openings.

2. The deposition mask of claim 1, further comprising:
a second inorganic layer including a first region disposed between the first surface of the base substrate and the first region of the first inorganic layer, a second region disposed between the second surface of the base substrate and the second region of the first inorganic layer, and a third region disposed between the third surface of the base substrate and the third region of the first inorganic layer.

3. The deposition mask of claim 2, wherein the second region of the second inorganic layer is disposed directly on the second region of the first inorganic layer.

4. The deposition mask of claim 2, wherein the first inorganic layer includes a silicon nitride and the second inorganic layer includes a silicon oxide.

5. The deposition mask of claim 1, further comprising:
an amorphous carbon layer disposed between the first surface of the base substrate and the first region of the first inorganic layer.

6. A method for manufacturing a deposition mask, comprising:
forming a first inorganic layer on a base substrate, wherein the first inorganic layer includes a first region, a second region, and a third region disposed on a first surface, a second surface, and a third surface of the base substrate, respectively;
forming a first hard mask layer on the first surface of the base substrate; and
forming cell openings in the first hard mask layer by etching the first hard mask layer and the first region of the first inorganic layer.

7. The method for manufacturing a deposition mask of claim 6, further comprising:
forming a second inorganic layer on the first hard mask layer and the first inorganic layer, wherein the second inorganic layer includes a first region, a second region, and a third region disposed on the first hard mask layer, the second region of the first inorganic layer, and the third region of the first inorganic layer, respectively;
forming a second hard mask layer on the first region of the second inorganic layer;
forming a third inorganic layer on the second hard mask layer;
forming a photoresist pattern on the third inorganic layer;
forming cell openings in the third inorganic layer by patterning the photoresist pattern;
forming cell openings in the second hard mask layer; and
forming cell openings in the first region of the second inorganic layer.

8. The method for manufacturing a deposition mask of claim 7, wherein:
the photoresist pattern partially exposes an edge of the third inorganic layer.

9. The method for manufacturing a deposition mask of claim 7, wherein forming the cell openings in the third inorganic layer comprises:
etching an edge of the third inorganic layer.

10. The method for manufacturing a deposition mask of claim 7, wherein forming cell openings in the second hard mask layer comprises:
etching an edge of the second hard mask layer.

11. The method for manufacturing a deposition mask of claim 7, wherein forming cell openings in the first region of the second inorganic layer comprises:
partially etching an edge of the second inorganic layer.

12. The method for manufacturing a deposition mask of claim 7, wherein forming cell openings in the first hard mask layer comprises:
removing the second hard mask layer.

13. The method for manufacturing a deposition mask of claim 7, wherein forming cell openings in the first region of the first inorganic layer comprises:
removing the first region of the second inorganic layer.

14. The method for manufacturing a deposition mask of claim 7, further comprising:
ashing the first hard mask layer.

15. The method for manufacturing a deposition mask of claim 7, further comprising:
forming opening patterns by etching the second region of the second inorganic layer, the second region of the first inorganic layer, and the base substrate.

16. The method for manufacturing a deposition mask of claim 7, further comprising:
forming opening patterns by etching the second region of the second inorganic layer, the second region of the first inorganic layer, the base substrate, and the first region of the first inorganic layer.

17. The method for manufacturing a deposition mask of claim 7, wherein:
the first hard mask layer and the second hard mask layer are amorphous carbon layers.

18. An electronic device, comprising:
a display device including a display panel formed using a deposition mask;
a memory having a stored application for operating the electronic device including the display device; and
a processor configured to execute the application stored in the memory,
wherein the deposition mask comprises:
a first inorganic layer including a first region disposed on a first surface of a base substrate, a second region disposed on a second surface of the base substrate, and a third region disposed on a third surface of the base substrate, wherein the first surface is opposite and parallel to the second surface, and wherein the third surface crosses the first surface and the second surface;
cell openings penetrating the first region of the first inorganic layer; and
opening patterns penetrating the second region of the first inorganic layer and the base substrate.

19. The electronic device of claim 18, wherein the deposition mask further comprises:
a second inorganic layer including a first region disposed between the first surface of the base substrate and the first region of the first inorganic layer, a second region disposed between the second surface of the base substrate and the second region of the first inorganic layer, and a third region disposed between the third surface of the base substrate and the third region of the first inorganic layer.

20. The electronic device of claim 18, wherein the deposition mask further comprises:
an amorphous carbon layer disposed between the first surface of the base substrate and the first region of the first inorganic layer.
